(19) United States
(12) Patent Application Publication
(10) Pub. No.: US 2017/0141245 A1
(43) Pub. Date: May 18, 2017

(54) CONDUCTIVE PASTE COMPOSITION AND SEMICONDUCTOR DEVICES MADE THEREWITH

(71) Applicant: E I DU PONT DE NEMOURS AND COMPANY, Wilmington, DE (US)

(72) Inventors: LAPKIN K. CHENG, BEAR, DE (US); NICHOLAS J. GLASSMAKER, WILMINGTON, DE (US); KURT RICHARD MIKESKA, HOCKESSIN, DE (US); CARMINE TORARDI, WILMINGTON, DE (US); PAUL DOUGLAS VERNOOY, HOCKESSIN, DE (US)

(21) Appl. No.: 14/939,689

(22) Filed: Nov. 12, 2015

(51) Int. Cl. H01L 31/0224; H01L 31/028; C09D 5/24; H01L 31/18

(52) U.S. Cl. CPC H01L 31/022425; H01L 31/18; H01L 31/028; C09D 5/24

(57) ABSTRACT

A conductive paste composition contains a source of an electrically conductive metal, a first oxide component comprising an alkali metal vanadium oxide composition, an optional second non-oxide, non-metal component, and an organic vehicle. An article such as a high-efficiency photovoltaic cell is formed by a process of deposition of the paste composition on a semiconductor device substrate (e.g., by screen printing) and firing the paste to remove the organic vehicle and sinter the metal and establish electrical contact between it and the substrate.

### CROSS-REFERENCE TO RELATED APPLICATION

This application claims benefit of U.S. Provisional Patent Application Ser. No. 62/079580, filed Nov. 14, 2014, and entitled “Conductive Paste Composition and Semiconductor Devices Made Therewith,” which application is incorporated herein in its entirety for all purposes by reference thereto.

### FIELD OF THE INVENTION

The present disclosure relates to a conductive paste composition that is useful in the construction of a variety of electrical and electronic devices, and more particularly to a paste composition useful in creating conductive structures, including electrodes for photovoltaic devices, devices constructed with such paste compositions, and a process for constructing these devices.

### TECHNICAL BACKGROUND

A conventional photovoltaic cell incorporates a semiconductor structure with a junction between semiconducting materials with different majority-carrier conductivity types, such as a p-n junction formed between an n-type semiconductor and a p-type semiconductor. More specifically, crystalline Si photovoltaic cells are typically made by adding controlled impurities (called dopants) to purified silicon, which is an intrinsic semiconductor. Dopants from IUPAC group 13 (e.g., B) are termed “acceptor dopants” and produce p-type material, in which the majority charge carriers are positive “holes,” or electron vacancies. Dopants from IUPAC group 15 (e.g., P) are termed “donor dopants” and produce n-type material, in which the majority charge carriers are negative electrons. Dopants may be added to bulk materials by direct inclusion in the melt during silicon crystal growth. Doping of a surface is often accomplished by providing the dopant at the surface in either liquid or gaseous form, and then thermally treating the base semiconductor to cause the dopants to diffuse inward. Ion implantation, possibly with further heat treatment, is also used for surface doping.

The cell structure includes a boundary or junction between p-type and n-type Si. When the cell is illuminated by electromagnetic radiation of an appropriate wavelength, such as sunlight, a potential (voltage) difference develops across the junction as the electron-hole pair charge carriers migrate into the electric field region of the p-n junction and become separated. The spatially separated charge carries are collected by electrodes in contact with the surfaces of the semiconductor. The cell is thus adapted to supply electric current to an electrical load connected to the electrodes, thereby providing electrical energy converted from the incoming solar energy that can do useful work. Since sunlight is almost always used, photovoltaic cells are commonly known as “solar cells.”

In the commonly used planar p-base configuration, a negative electrode is located on the side of the cell that is to be exposed to a light source (the “front” or “light-receiving” side, which in the case of an ordinary solar cell is the side exposed to sunlight), and a positive electrode is located on the other side of the cell (the “back” or “non-illuminated” side). Cells having a planar n-base configuration, in which the p- and n-type regions are interchanged from the p-base configuration, are also known. Solar-powered photovoltaic systems are considered to be environmentally beneficial in that they reduce the need for burning fossil fuels in conventional electric power plants.

Industrial photovoltaic cells are commonly provided in the form of a structure, such as one based on a doped crystalline silicon wafer, that has been metallized, i.e., provided with electrodes in the form of electrically conductive metal contacts through which the generated current can flow to an external electrical circuit load. Most commonly, these electrodes are provided on opposite sides of a generally planar cell structure. Conventionally, they are produced by applying suitable conductive metal pastes to the respective surfaces of the semiconductor body and thereafter firing the pastes.

Photovoltaic cells are commonly fabricated with an insulating layer on their front side to afford an anti-reflective property that maximizes the utilization of incident light. However, in this configuration, the insulating layer normally must be removed to allow an overlaid front-side electrode to make contact with the underlying semiconductor surface. Conductive metal pastes typically appointed for forming front side electrodes include a glass frit and a conductive species (e.g., silver particles) carried in an organic medium that functions as a vehicle for printing. The electrode may be formed by depositing the paste composition in a suitable pattern (for instance, by screen printing) and thereafter firing the paste composition and substrate to dissolve or otherwise penetrate the insulating, anti-reflective layer and sinter the metal powder, such that an electrical connection with the semiconductor structure is formed.

The ability of the paste composition to penetrate or etch through the anti-reflective layer and form a strongly adhering bond between the electrode and the substrate upon firing is highly but unpredictably dependent on the composition of the conductive paste and the firing conditions. Key measures of photovoltaic cell electrical performance, such as light conversion efficiency, are also influenced by the quality of the electrical contact made between the fired conductive paste and the substrate.

Although various methods and compositions useful in forming devices such as photovoltaic cells are known, there nevertheless remains a need for compositions that permit fabrication of patterned conductive structures that provide improved overall device electrical performance and that facilitate the efficient manufacture of such devices in both conventional and novel architectures.

### SUMMARY OF THE INVENTION

An embodiment of the present disclosure provides a paste composition, comprising: an inorganic solids portion that comprises:
(a) a first, oxide-based component comprising an alkali metal vanadium oxide composition,
(b) an optional second, non-metallic, non-oxide component,
(c) a source of electrically conductive metal, and

an organic vehicle in which the constituents of the inorganic solids portion are dispersed.

Another embodiment provides a process for forming an electrically conductive structure on a substrate, the process comprising:
(a) providing a substrate having opposed first and second major surfaces;
(b) applying the foregoing paste composition onto a first preselected portion of the first major surface; and
(c) firing the substrate and paste composition thereon, whereby the electrically conductive structure is formed on the substrate.

A further embodiment provides a process for forming an electrically conductive structure on a substrate, the process comprising:
(a) providing a substrate having opposed first and second major surfaces;
(b) applying the foregoing paste composition onto a first preselected portion of the first major surface and onto a separate second preselected portion of one of the major surfaces; and
(c) firing the substrate and paste composition thereon, whereby separate electrically conductive structures are formed on the respective preselected portions of the substrate.

The respective preselected portions may be on either the same or opposite major surfaces of the substrate, and the electrodes may be formed respectively on n-type and p=type semiconductor material.

Also disclosed are articles that are formed using the present paste composition in the practice of the foregoing processes. Such articles include semiconductor devices and photovoltaic cells. The present processes can be used to form electrodes contacting either p-type or n-type regions of silicon semiconductors, the electrodes comprising electrically conductive structures formed by any of the processes described herein.

### BRIEF DESCRIPTION OF THE DRAWINGS

The invention will be more fully understood and further advantages will become apparent when reference is made to the following detailed description of the preferred embodiments of the invention and the accompanying drawings, wherein like reference numerals denote similar elements throughout the several views and in which:

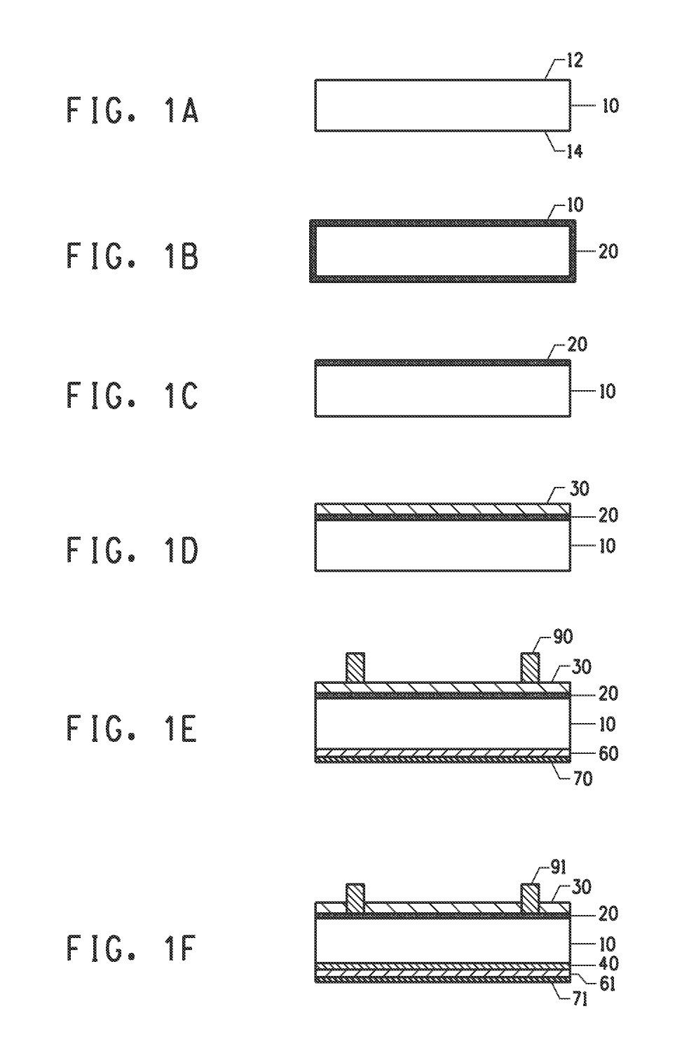

FIGS. 1A-1F illustrate successive steps of a process by which a semiconductor device may be fabricated. The device in turn may be incorporated into a photovoltaic cell. Reference numerals as used in FIGS. 1A-1F include the following:
10: p-type substrate;
12: first major surface (front or light-receiving side) of substrate 10;
14: second major surface (back side) of substrate 10;
20: n-type diffusion layer;
30: insulating layer;
40: p+ layer;
60: aluminum paste formed on back side;
61: aluminum back electrode (obtained by firing back-side aluminum paste);
70: silver or silver/aluminum paste formed on back side;
71: silver or silver/aluminum back electrode (obtained by firing back-side paste);
90: conductive paste as provided herein and formed on front side; and
91: conductive front electrode, formed by firing the front-side conductive paste).

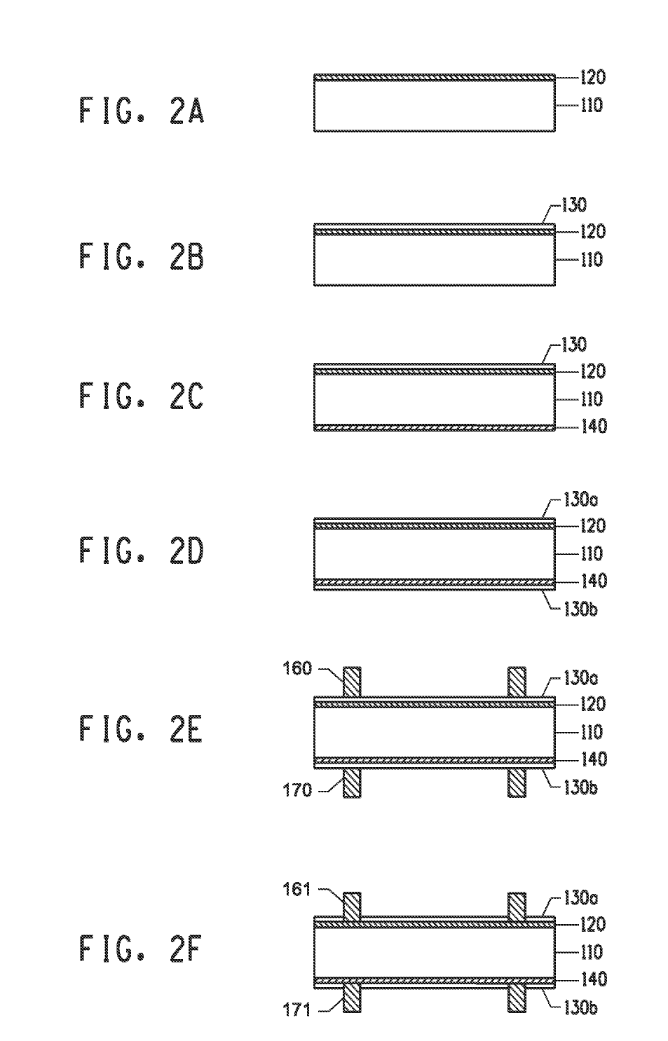

FIGS. 2A-2F illustrate successive steps of another process by which a semiconductor device may be fabricated. This also may be incorporated into a photovoltaic cell. Reference numerals as used in FIGS. 2A-2F include the following:
110: n-type substrate;
120: p-type emitter;
130a: front major surface passivation layer;
130b: rear major surface passivation layer;
140: n⁺ layer;
160: conductive paste;
161: p-type electrode;
170: conductive paste; and
171: n-type electrode.

### DETAILED DESCRIPTION

Various aspects of the present disclosure relate to the need for high performance semiconductor and other electronic devices having mechanically robust and durable, high conductivity electrodes as well as processes suitable for their manufacture. In one aspect, the conductive paste composition provided herein is beneficially employed in the fabrication of such electrodes of photovoltaic devices. Ideally, a paste composition promotes the formation of a metallization that: (a) adheres strongly to the underlying semiconductor substrate; and (b) provides a relatively low resistance contact with the substrate. Suitable paste compositions are believed to aid in etching surface insulating layers, which are ordinarily included in semiconductor structures such as photovoltaic cells, as required for making good contact between the conductive electrode and the underlying semiconductor.

In an aspect, a paste composition is provided that comprises: a functional conductive component, such as a source of electrically conductive metal; a first, oxide-based component comprising an oxide based on alkali metal and vanadium cations; an optional second, non-oxide, non-metal additive component; and an organic vehicle. Certain embodiments involve a photovoltaic cell that includes one or more conductive structures made with the present paste composition. Such cells may provide in some implementations any combination of one or more of high photovoltaic conversion efficiency, high fill factor, and low series resistance.

In certain embodiments, the present paste composition may comprise an inorganic solids portion comprising (a) about 75% to about 99.5% by weight, or about 90% to about 99% by weight, or about 95% to about 99% by weight, of a source of an electrically conductive metal; (b) about 1% to about 15% by weight, or about 1% to about 8% by weight, or about 2% to about 6% by weight, or about 1% to about 5% by weight, or about 1% to about 3% by weight, of a first, oxide-based component comprising an alkali metal vanadium oxide composition, especially one including cesium; and (c) up to about 2%, 4%, 6%, or 8% of an optional second component that is non-oxide and non-metallic. The above stated contents of constituents (a), (b), and (c) are based on the total weight of all the constituents of the inorganic solids portion of the composition, apart from the organic medium.

As further described below, the paste composition also comprises an organic vehicle, which acts as a carrier for the inorganic constituents, which are dispersed therein. Along with solvent, the organic vehicle may include one or more components such as polymers, surfactants, thickeners, thixotropes, and binders that may impart desirable functional properties, including without limitation ones desirable in deposition and electrode formation processes.

Typically, electrodes or other like conductive traces are provided by screen printing the paste composition onto a substrate, although other forms of deposition may alternatively be used, including without limitation plating, extrusion or co-extrusion, dispensing from a syringe, inkjet, shaped, multiple, or ribbon printing. After deposition, the composition is fired at an elevated temperature. A separate drying step is optionally carried out prior to the actual firing.

The composition also can be used to form conductive traces for other purposes, such as those employed in a semiconductor module that is to be incorporated into an electrical or electronic device. As would be recognized by a skilled artisan, the paste composition described herein can be termed “conductive,” meaning that the composition can be formed into a structure and thereafter processed to exhibit an electrical conductivity sufficient for conducting electrical current between devices and circuitry connected thereto.

### I. Inorganic Components

An aspect of the present disclosure relates to a paste composition, which may include: an inorganic solids portion comprising a functional material providing electrical conductivity, an oxide-based component comprising an oxide comprising alkali metal and vanadium cations, and an optional, non-oxide, non-metal component; and an organic vehicle in which the inorganic solids are dispersed.

### A. Electrically Conductive Metal

The present paste composition includes a source of an electrically conductive metal. Exemplary metals include without limitation silver, gold, copper, nickel, palladium, platinum, aluminum, and alloys and mixtures thereof. Silver is preferred for its processability and high conductivity. In some embodiments, the electrically conductive metal consists essentially of silver. However, a composition including at least some non-precious metal may be used to reduce cost or to modify other properties.

The conductive metal may be incorporated directly in the present paste composition as a metal powder. In another embodiment, a mixture of two or more such metals or an alloy is directly incorporated. Alternatively, the metal is supplied by a metal oxide or salt that decomposes upon exposure to the heat of firing to form the metal. As used herein, the term “silver” is to be understood as referring to elemental silver metal, alloys of silver, and mixtures thereof, and may further include silver derived from silver oxide (Ag₂O or AgO) or silver salts such as AgCl, AgNO₃, AgOOCCH₃ (silver acetate), AgOOCF₃ (silver trifluoroacetate), Ag₃PO₄ (silver orthophosphate), or mixtures thereof. Any other form of conductive metal compatible with the other components of the paste composition also may be used in certain embodiments. Other metals used in the present paste for the functional conductive material may be similarly derived.

In some embodiments, the electrically conductive metal is substantially Al-free, meaning that the paste composition does not include aluminum (Al) metal or any aluminum-containing material that decomposes to provide aluminum metal or aluminum-containing metal or metal alloy, and that the amount of aluminum present as an impurity ordinarily is less than 0.1 wt. %. However, it is understood that the oxide component may still contain aluminum oxide

Electrically conductive metal powder used in the present paste composition may be supplied as finely divided particles having any morphology, including without limitation, any one or more of the following morphologies: a powder form, a flake form, a spherical form, a rod form, a granular form, a nodular form, a layered or coated form, other irregular forms, or mixtures thereof. The electrically conductive metal or source thereof may also be provided in a colloidal suspension, in which case the colloidal carrier would not be included in any calculation of weight percentages of the solids of which the colloidal material is part.

The particle size of the metal is not subject to any particular limitation. As used herein, “particle size” is intended to refer to “median particle size” or d₅₀, by which is meant the 50% volume distribution size. The particle size distribution may also be characterized by d₉₀, meaning that 90% by volume of the particles are smaller than d₉₀. Volume distribution size may be determined by a number of methods understood by one of skill in the art, including but not limited to laser diffraction and dispersion methods employed by a Microtrac particle size analyzer (Montgomeryville, Pa.). Laser light scattering, e.g., using a model LA-910 particle size analyzer available commercially from Horiba Instruments Inc. (Irvine, Calif.), may also be used. In various embodiments, the median size of the metal particles is greater than 0.2 μm and less than 10 μm, or the median particle size is greater than 0.4 μm and less than 5 μm, as measured using the Horiba LA-910 analyzer.

As further described below, the electrically conductive metal or a source thereof can be dispersed in an organic vehicle that acts as a carrier for the metal phase and other constituents present in the formulation. The electrically conductive metal may comprise any of a variety of percentages of the composition of the paste composition. To attain high conductivity in a finished conductive structure, it is generally preferable for the concentration of the electrically conductive metal to be as high as possible while maintaining other required characteristics of the paste composition that relate to either processing or final use, such as the need for a uniform, mechanically robust and adherent contact and adequate penetration of any surface passivation and/or antireflective coating present on the substrate. Minimizing the bulk resistivity and the contact resistance between the conductive structure and the underlying device beneficially tends to decrease the source resistance of a device.

In an embodiment, the silver or other electrically conductive metal may comprise about 75% to about 99.5% by weight, or about 85% to about 99% by weight, or about 95% to about 99% by weight, of the inorganic solid components of the paste composition.

In another embodiment, the solids portion of the paste composition may include about 80 wt. % to about 90 wt. % silver particles and about 1 wt. % to about 9 wt. % silver flakes. In an embodiment, the solids portion of the paste composition may include about 70 wt. % to about 90 wt. % silver particles and about 1 wt. % to about 9 wt. % silver flakes. In another embodiment, the solids portion of the paste composition may include about 70 wt. % to about 90 wt. % silver flakes and about 1 wt. % to about 9 wt. % of colloidal silver. In a still further embodiment, the solids portion of the paste composition may include about 60 wt. % to about 90 wt. % of silver particles or silver flakes and about 0.1 wt. % to about 20 wt. % of colloidal silver.

The electrically conductive metal used herein, particularly when in powder form, may be coated or uncoated; for example, it may be at least partially coated with a surfactant to facilitate processing. Suitable coating surfactants include, for example, stearic acid, palmitic acid, a salt of stearate, a salt of palmitate, and mixtures thereof. Other surfactants that also may be utilized include lauric acid, oleic acid, capric acid, myristic acid, linoleic acid, and mixtures thereof. Still other surfactants that also may be utilized include polyethylene oxide, polyethylene glycol, benzotriazole, poly(ethylene glycol)acetic acid, and other similar organic molecules. Suitable counter-ions for use in a coating surfactant include without limitation hydrogen, ammonium, sodium, potassium, and mixtures thereof. When the electrically conductive metal is silver, it may be coated, for example, with a phosphorus-containing compound.

In an embodiment, one or more surfactants may be included in the organic vehicle in addition to any surfactant included as a coating of conductive metal powder used in the present paste composition.

The conductive metal is present in some embodiments as a metal powder of any one or more of silver, gold, copper, nickel, palladium, platinum, aluminum, and alloys and mixtures thereof in an amount ranging from a metal source lower limit to a metal source upper limit, the metal source lower limit being one of 70%, 75%, 80%, or 85%, and the metal source upper limit being one of 85%, 90%, 95%, 99%, or 99.5%, based on the weight of the inorganic solids. Alternatively, the conductive metal may be included in the paste composition in an amount ranging from a metal lower limit to a metal upper limit, the metal lower limit being one of 65%, 70%, 75%, 80%, or 85%, and the metal upper limit being one of 85%, 90%, 95%, or 97%, based on the weight of the paste composition. In some embodiments, the conductive metal powder may be coated with another metal or other material to alter its reactivity.

### B. Oxide-Based Component

The present paste composition may include a first, oxide-based component, which is understood to refer to a composition containing anions of one or more types, of which at least 80% are oxygen anions, and cations. The oxide-based component of the present paste composition may comprise a single, homogeneously mixed material or plural constituent materials that have different, identifiable compositions.

### Alkali Metal Vanadium Oxide Composition

Embodiments of the present paste composition include a first, oxide-based component that comprises an alkali metal vanadium oxide composition. As used herein, the term “alkali metal vanadium oxide composition” refers to a composition containing at least alkali metal (nominally represented as “A”) and vanadium (V) cations and oxygen (O) anions that are homogeneously mixed. In some embodiments, substantially all the anions are oxygens, while in others, up to 20% of the oxygen anions are halogen or other anions instead.

The anions and cations of the alkali metal vanadium oxide composition may be homogeneously mixed, meaning that the constituent anions and cations are intimately chemically mixed at an atomic level during preparation of the composition. For example, the material in the composition may be subjected to melting or other operation to effect intimate mixing. It is to be understood that, upon cooling after being fully melted, some mixed oxides may phase segregate in a microstructure having grains, regions, or domains having different compositions. Such a microstructure is still to be regarded as having intimately mixed cations.

Such mixing is distinguished from a physical mixing, after which multiple constituent, possibly particulate, materials made up of macroscopic particles remain differentiated throughout the entire preparation, e.g. as would result from the mixing different powders without melting them together at any point.

In some embodiments, the oxide-based component comprises an alkali metal metavanadate, a crystalline compound having the nominal formula AVO₃, wherein A is any of the isovalent alkali metals Li, Na, K, Rb, Cs, or a mixture thereof in any proportion. The AVO₃ compound may comprise an amount ranging from a lower limit of 25, 35, 50, or 75% to an upper limit of 85, 90, 95, or 97% by weight of the first component. In an embodiment, the first component consists essentially of an AVO₃ compound. In various embodiments, a ratio of an aggregate amount of the discrete oxide to an amount of AVO₃ present in the first component ranges from 0 to 0.25, 0.33, 0.5, 0.75, 1, or 1.5 by weight. Embodiments also include ones in which the AVO₃ compound is present in an amount ranging from a lower limit to an upper limit, the lower limit being one of 0.1%, 0.2%, 0.5%, 1%, 1.5%, or 2%, and the upper limit being one of 2.5%, 3%, 3.5%, 4%, 5%, 7.5%, or 10% by weight of the paste composition.

In another embodiment, the oxide-based component comprises a crystalline alkali metal vanadium oxide having a formula (A²)V₂O_{5.5}, wherein A² is one of Li, Na, K, Rb, Cs, or a mixture thereof in any proportion.

In still another embodiment, the oxide-based component comprises a crystalline alkali metal vanadium oxide having a formula (A³)V₃O₈, wherein A³ is one of Li, Na, K, Rb, Cs, or a mixture thereof in any proportion.

Some embodiments of the present paste composition incorporate a first component that includes an alkali metal vanadium oxide composition having an atomic composition different from that of pure AVO₃. For example, the alkali metal vanadium oxide composition may comprise A cations and V cations in respective cation percentages of “x” and “y”, with a value of the sum “w”=(x+y) that is between a lower limit of 50, 60, 70, 80, 90, or 95 cation % and an upper limit of 100 cation %.

In another embodiment, the alkali metal vanadium oxide composition comprises A cations and V cations in respective cation percentages of “x” and “y”, with a value of the ratio “z”=x/(x+y) that is between a lower limit and an upper limit, the lower limit being one of 0.3, 0.35, 0.4, 0.45, or 0.5, and the upper limit being one of 0.55, 0.6, and 0.65. In still another embodiment, the alkali metal vanadium oxide composition comprises A cations and V cations in respective cation percentages of “x” and “y”, with a value of the sum “w”=(x+y) that is between a lower limit of 50, 60, 70, 80, 90, or 95 cation % and an upper limit of 100 cation % and a value of the ratio “z”=x/(x+y) that is between a lower limit and an upper limit, the lower limit being one of 0.3, 0.35, 0.4, 0.45, or 0.5, and the upper limit being one of 0.55, 0.6, and 0.65. In general, lowering the alkali metal:V cation ratio in the oxide component necessitates a higher total amount of the component in the paste composition, to obtain the same activity from the alkali metal cations. A higher V content generally lowers the melting or softening temperature of the oxide.

It is to be understood that in any of the foregoing embodiments, the alkali metal nominally designated “A” can be one of Li, Na, K, Rb, Cs, or a mixture thereof in any proportion, or one of K, Rb, Cs, or a mixture thereof in any proportion, or one of Rb, Cs, or a mixture thereof in any proportion, or substantially entirely Cs. In further embodiments, the alkali metal comprises at least 40%, 50%, 60%, 70%, 80%, or 90% (by cation percentage) of one or both of Cs and Rb; or at least 40%, 50%, 60%, 70%, 80%, or 90% of one or more of Cs, Rb, and K, with at most 50% being K (by cation percentages).

While the alkali metal and V cations in the paste composition are ordinarily present in their normal 1+ and 5+ valences, respectively, it is possible that some or all of the V or other cations may be in another valence state, so that one or more non-stoichiometric oxides may be present.

The alkali metal vanadium oxide composition incorporated in the first component of the present paste composition may be provided as a finely divided powder, and may be either crystalline or partially or fully glassy or amorphous. Depending on its elemental content and preparation history, an oxide composition that is partially or fully crystalline may comprise a single or multiple crystalline phases. As recognized by a skilled person, melting and then solidifying a composition that does not correspond to a single crystalline phase in some instances may result in a microstructure having regions with different compositions and atomic structure, even though the various constituent elements initially were intimately mixed by complete melting. For example, an exemplary oxide composition useful in the present paste composition was made by melting together a physical mixture of 38 wt. % Cs₂CO₃ and 62 wt. % V₂O₅. After the material was re-solidified, it was found by powder X-ray diffraction to be non-glassy and to contain about 32 wt. % crystalline CsVO₃ metavanadate and 68 wt. % crystalline CsV₂O₅₅, another possible cesium vanadium oxide compound. Since the Cs and V cations and the oxygen anions of this material were intimately chemically mixed during the melting operation, the re-solidified material is regarded as being a homogeneous, intimate mixture, even though it has a polycrystalline microstructure wherein grains of the two crystalline constituents are identifiably present, albeit intermingled.

Embodiments of the present disclosure may incorporate an oxide-based component that includes any one or more crystalline oxide phases containing both alkali metal and vanadium cations, such as one or both of the aforementioned phases having the nominal formulas AVO₃ and (A)V₂O_{5.5}, as well as possibly including crystalline oxide phases containing just one of alkali metal and vanadium cations, such as (A¹)₂O, (A³)V₃O₅, or V₂O₅. In the foregoing formulas, A, A¹, A², and A³ separately represent any of the alkali metals Li, Na, K, Rb, or Cs, or a combination thereof.

At least a portion of the first component of the present paste composition is a fusible oxide material. The term “fusible,” as used herein, refers to the ability of a material to become fluid upon heating, such as the heating employed in a firing operation. In some embodiments, the fusible material is composed of one or more fusible subcomponents. For example, the fusible material may comprise a glass material, or a mixture of two or more glass materials. Glass material in the form of a fine powder, e.g., as the result of a comminution operation, is often termed “frit” and is readily incorporated in the present paste composition. Of course, crystalline materials incorporated in the present paste composition may also be fusible. In most embodiments, at least the alkali metal oxide composition is a fusible material.

A median particle size of the alkali metal vanadium oxide composition in the present composition may be in the range of about 0.5 to 10 μm, or about 0.8 to 5 μm, or about 1 to 3 μm, as measured using the Horiba LA-910 analyzer.

As used herein, the term “glass” refers to a particulate solid form, such as an oxide or oxyfluoride, that is at least predominantly amorphous, meaning that short-range atomic order is preserved in the immediate vicinity of any selected atom, that is, in the first coordination shell, but dissipates at greater atomic-level distances (i.e., there is no long-range periodic order). Hence, the X-ray diffraction pattern of a fully amorphous material exhibits broad, diffuse peaks, and not the well-defined, narrow peaks of a crystalline material. In the latter, the regular spacing of characteristic crystallographic planes give rise to the narrow peaks, whose position in reciprocal space is in accordance with Bragg's law. A glass material also does not show a substantial crystallization exotherm upon heating close to or above its glass transition temperature or softening point, T_{g}, which is defined as the second transition point seen in a differential thermal analysis (DTA) scan. In an embodiment, the softening point of glass material used in the present paste composition is in the range of 300 to 800° C. In other embodiments, the softening point is in the range of 250 to 650° C., or 300 to 500° C., or 300 to 400° C.

It is contemplated that some or all of the alkali metal vanadium oxide material herein may be composed of material that exhibits some degree of crystallinity. For example, in some embodiments, a plurality of oxides are melted together, resulting in a material that is partially amorphous and partially crystalline. As would be recognized by a skilled person, such a material would produce an X-ray diffraction pattern having narrow, crystalline peaks superimposed on a pattern with broad, diffuse peaks. Alternatively, one or more constituents, or even substantially all of the fusible material, may be predominantly or even substantially fully crystalline. In an embodiment, crystalline material useful in the fusible material of the present paste composition may have a melting point of at most 750, 800, or 850° C.

The alkali metal vanadium oxide composition included in the present paste composition optionally incorporates other oxides in intimate admixture, including oxides of one or more of the additional cations B, Al, Mg, Ca, Sr, Ba, Ti, Mn, Fe, Co, Ni, Cu, Zn, Zr, Nb, Si, Mo, Hf, Ta, W, Pb, Ag, Ga, Ge, In, Sn, Sb, Se, Ru, Bi, P, Te, Y, La or the other lanthanide elements, or mixtures thereof. (The term “lanthanide elements” is understood to include the elements of the periodic table having atomic numbers of 57 through 71, i.e., La—Lu.) This list is meant to be illustrative, not limiting.

In various embodiments, the alkali metal vanadium oxide composition used in present paste composition may incorporate any one or more of the oxides of the foregoing additional cations, or any mixture thereof, in an aggregate amount up to an upper admixture limit of 5%, 10%, 15%, 20%, 25%, 30%, 35%, 40%, or 50% of the total cations in the alkali metal vanadium oxide composition. In some embodiments, silver oxide is included at up to 10 cation %, or 15 cation %, or 20 cation %. Such substances may be intimately mixed at an atomic level in the alkali metal vanadium oxide composition, e.g., by melting the substances together.

In other embodiments, the oxide based component comprises:
(a) alkali metal cations in a cation percentage “a” ranging from 15 to 50;
(b) vanadium cations in a cation percentage “b” ranging from 20 to 70;
(c) alkaline earth metal cations in a cation percentage “c” ranging from 0 to 20; and
(d) phosphorus cations in a cation percentage “d” ranging from 0 to 20,
wherein the cation percentages a, b, c, and d are based on the total oxide-based component.
   The alkaline earth metals employed may be any one of Mg, Ca, Sr, Ba, or a mixture thereof in any proportion.

In one such embodiment, a ratio a/(a+b) is at least 0.25 and c is at most 15 cation %; a ratio a/(a+b) is at least 0.40 and c is at most 20 cation %; or a ratio a/(a+b) is at least 45 and c is at most 25 cation %. In another such embodiment, Cs cations comprise more than 95% of the total alkali metal cations and a ratio a/(a+b) is at least 0.10; Cs cations comprise more than 95% of the total alkali metal cations and c is at most 10 cation %; or Cs cations comprise between 30% and 95% of the total alkali metal cations.

In still another such embodiment, c is 2, 5, 10, 15, or 20 cation %. In yet another embodiment, d is 2, 5, 10, 15, or 20 cation %.

Although oxygen is typically the predominant anion in the oxide-based component of the present paste composition, some portion of the oxygen may be replaced chemically by fluorine or other halogen anions to alter certain properties, such as chemical, thermal, or rheological properties, of the oxide component that affect firing. In an embodiment, up to 10% of the oxygen anions of the alkali metal vanadium oxide composition in any of the formulations of the present paste composition are replaced by one or more halogen anions, including fluorine. For example, up to 10% of the oxygen anions may be replaced by fluorine. Halogen anions may be supplied from halides of any of the composition's cations.

For example, one of ordinary skill would recognize that embodiments wherein the alkali metal vanadium oxide composition contains fluorine can be prepared using fluorine anions supplied from a simple fluoride or an oxyfluoride. In an embodiment, the desired fluorine content can be supplied by replacing some or all of an oxide nominally incorporated in the composition with the corresponding fluoride of the same cation, such as by replacing some or all of the Cs₂O nominally included with the amount of CsF needed to attain the desired level of F content. Of course, the requisite amount of F can be derived by replacing the oxides of more than one included cation if desired. Other fluoride sources could also be used, including sources such as ammonium fluoride that would decompose during the heating in typical glass preparation to leave behind residual flourine anions.

The alkali metal vanadium oxide composition may be present in the paste composition in an amount ranging from a lower limit to an upper limit, the lower limit being one of 0.1%, 0.2%, 0.5%, 1%, 1.5%, or 2%, and the upper limit being one of 2.5%, 3%, 3.5%, 4%, 5%, 7.5%, or 10% by weight of the paste composition.

One of ordinary skill in the art of glass chemistry would recognize that various components of the present paste composition, including both the oxide-based component and any constituent thereof, are described herein as including percentages of certain components. Specifically, the composition of these substances are specified by denominating individual components that may be combined in the specified percentages to form a starting material that subsequently is processed, e.g., as described herein, to form a glass or other fusible material. Such nomenclature is conventional to one of skill in the art. In other words, the oxide-based component and/or the alkali metal composition contain certain components, and the percentages of those components may be expressed as weight percentages of the corresponding oxide or other forms.

Alternatively, some of the compositions herein are set forth by cation percentages, which are based on the total cations contained in the particular material, unless otherwise indicated by the context. Of course, compositions thus specified include the oxygen or other anions associated with the various cations. A skilled person would recognize that compositions could equivalently be specified by weight percentages of the constituents, and would be able to perform the required numerical conversions.

A skilled person would further recognize that any of the alkali metal vanadium oxide compositions or other like materials herein, whether specified by weight percentages or cation percentages of the constituent oxides, may alternatively be prepared by supplying the required anions and cations in requisite amounts from different components that, when mixed and fired, yield the same overall composition. For example, in various embodiments, cesium for the compound CsVO₃ could be supplied either from Cs₂O or alternatively from a suitable organic or inorganic cesium-containing compound (such as Cs₂CO₃) that decomposes on heating to yield Cs₂O. The skilled person would also recognize that a certain portion of volatile species, e.g., carbon dioxide, may be released during the process of making a fusible material.

It is known to those skilled in the art that an oxide composition such as one prepared by a melting technique as described herein may be characterized by known analytical methods that include, but are not limited to: Inductively Coupled Plasma-Emission Spectroscopy (ICP-ES), Inductively Coupled Plasma-Atomic Emission Spectroscopy (ICP-AES), and the like. In addition, the following exemplary techniques may be used: X-Ray Fluorescence spectroscopy (XRF), Nuclear Magnetic Resonance spectroscopy (NMR), Electron Paramagnetic Resonance spectroscopy (EPR), Mössbauer spectroscopy, electron microprobe Energy Dispersive Spectroscopy (EDS), electron microprobe Wavelength Dispersive Spectroscopy (WDS), and Cathodoluminescence (CL). A skilled person could calculate percentages of starting components that could be processed to yield a particular fusible material, based on results obtained with such analytical methods.

The embodiments of the various alkali metal vanadium oxide composition described in the present specification, including the examples below, are not limiting; it is contemplated that one of ordinary skill in the art of glass chemistry could make minor substitutions of additional ingredients and not substantially change the desired properties of the alkali metal vanadium oxide composition, including its interaction with a substrate and any insulating layer thereon.

In an embodiment, the alkali metal vanadium oxide composition may be produced by conventional glass-making techniques and equipment. For example, the ingredients may be weighed and mixed in the requisite proportions and then heated in a platinum alloy crucible in a furnace. The ingredients may be heated to a peak temperature (e.g., 800° C. to 1400° C., or 1000° C. to 1200° C., or 900° C. to 1050° C.) and held for a time such that the material forms a melt that is substantially liquid and homogeneous (e.g., 20 minutes to 2 hours). The melt optionally is stirred, either intermittently or continuously. In an embodiment, the melting process results in a material wherein the constituent chemical elements are homogeneously and intimately mixed at an atomic level. The molten material is then typically quenched in any suitable way including, without limitation, passing it between counter-rotating stainless steel rollers to form 0.25 to 0.50 mm thick platelets, by pouring it onto a thick stainless steel plate, or by pouring it into a suitable quench fluid. The resulting particles are then milled to form a powder or frit, which typically may have a d₅₀ of 0.2 to 3.0 μm.

Other production techniques may also be used for the present alkali metal vanadium oxide composition and other oxide-based materials. One skilled in the art of producing such materials might therefore employ alternative synthesis techniques including, but not limited to, melting in non-precious metal crucibles, melting in ceramic crucibles, sol-gel, spray pyrolysis, or others appropriate for making powder forms of glass.

### Oxide Additive

The oxide-based component of the present paste composition optionally may further comprise a discrete oxide additive. It is contemplated that the additive may comprise a discrete oxide of one element or a discrete oxide of multiple elements. As used herein, the term “oxide of an element” includes both the oxide compound itself and any other organic or inorganic compound of the element, or the pure element itself if it oxidizes or decomposes on heating to form the pertinent oxide. Such compounds known to decompose upon heating include, but are not limited to, carbonates, nitrates, nitrites, hydroxides, acetates, formates, citrates, and soaps of the foregoing elements, and mixtures thereof. For example, Zn metal, zinc acetate, zinc carbonate, and zinc methoxide are potential additives that would oxidize or decompose to form zinc oxide upon firing. The oxide is discrete, in that it is not mixed at an atomic level with the base alkali metal vanadium oxide composition, but is separately formulated and present in the paste composition. In an embodiment, the discrete oxide additive may be present in the paste composition in an amount ranging from 0.01 to 5 wt. %, or 0.05 to 2.5 wt. %, or 0.1 to 1 wt. %, based on the total weight of the paste composition. In various embodiments, a ratio of an aggregate amount of the discrete oxide to an amount of cesium vanadium oxide composition present in the first component ranges from 0 to 0.25, 0.33, 0.5, 0.75, 1, or 1.5 by weight.

In an embodiment, the discrete oxide additive is an oxide of one or more of Al, Li, Na, K, Rb, Cs, Mg, Ca, Sr, Ba, Ti, V, Mn, Fe, Co, Ni, Cu, Zn, Zr, Nb, Te, Si, Mo, Hf, W, Pb, Ag, Ga, Ge, In, Sn, Sb, Se, Ru, Bi, P, Y, La, the other lanthanide elements, or mixtures thereof, or a substance that forms such an oxide upon heating. In other embodiments, the discrete oxide additive is an oxide of one or more of Al, Li, Na, K, Rb, Cs, Ba, Ti, Zn, or Zr. Particles of the oxide or non-oxide additives of any size can be employed, as long as they can be incorporated into the present paste composition and provide its required functionality.

Any size-reduction method known to those skilled in the art can be employed to reduce particle size of the oxide and non-oxide constituents of the present paste composition to a desired level. Such processes include, without limitation, ball milling, media milling, jet milling, vibratory milling, and the like, with or without a solvent present. If a solvent is used, water is the preferred solvent, but other solvents may be employed as well, such as alcohols, ketones, and aromatics. Surfactants may be added to the solvent to aid in the dispersion of the particles, if desired.

Although in some embodiments the present paste composition (including the oxide and non-oxide materials contained therein) may contain a small amount of lead, lead oxide, or other lead compound, e.g., in the alkali metal vanadium oxide composition, other embodiments are lead-free. As used herein, the term “lead-free paste composition” refers to a paste composition to which no lead has been specifically added (either as elemental lead or as a lead-containing alloy, compound, or other like substance), and in which the amount of lead present as a trace component or impurity is 1000 parts per million (ppm) or less by weight. In some embodiments, the amount of lead present as a trace component or impurity is less than 500 ppm, or less than 300 ppm, or less than 100 ppm. Surprisingly and unexpectedly, photovoltaic cells exhibiting desirable electrical properties, such as high conversion efficiency, are obtained using some embodiments of the paste composition and process of the present disclosure, notwithstanding previous belief in the art that substantial amounts of lead must be included in a paste composition to attain these end-use benefits.

Similarly, some embodiments of the present paste composition may comprise cadmium, e.g., in the alkali metal vanadium oxide composition, while others are cadmium-free, again meaning that no Cd metal or compound is specifically added and that the amount present as a trace impurity is less than 1000 ppm, 500 ppm, 300 ppm, or 100 ppm by weight.

Embodiments of the present paste include ones in which the first component is present in an amount between a first lower limit and a first upper limit, the first lower limit being one of 0.25%, 0.5%, and 1% and the first upper limit being one of 1.5%, 2%, 2.5%, 3%, 4%, 5%, 7.5%, 10%, or 12%, the amounts being measured by weight percentage of the paste composition.

In another alternative, the first oxide-based component of the present paste composition may comprise a plurality of separate fusible substances, such as one or more frits, a substantially crystalline material with additional frit material, or a plurality of crystalline materials, such that during a firing operation, the materials melt and become intimately mixed. In an embodiment, a first fusible subcomponent is chosen for its capability to rapidly etch an insulating layer, such as that typically present on one or both surfaces of a photovoltaic cell; further, the first fusible subcomponent may have strong etching power and low viscosity. A second fusible subcomponent is optionally included to slowly blend with the first fusible subcomponent to alter the chemical activity. Preferably, the composition is such that the insulating layer is partially removed but without attacking the underlying emitter-diffused region, which would shunt the device, were the corrosive action to proceed unchecked. Such fusible materials may be characterized as having a viscosity sufficiently high to provide a stable manufacturing window to remove insulating layers without damage to the diffused p-n junction region of a semiconductor substrate. Ideally, the firing process results in a substantially complete removal of the insulating layer without further combination with the underlying Si substrate or the formation of substantial amounts of non-conducting or poorly conducting inclusions.

### C. Non Oxide, Non-Metal Oxide Component

Certain embodiments of the present paste composition include a second, non-oxide component. For example, the second component may comprise, without limitation, one or more of a phosphide, a carbide, a silicide, or a nitride. It is to be understood that some possible non-metallic second components may exhibit physical properties ordinarily regarded as metallic, including, inter alia, metallic electrical conductivity. Second component materials may also be semi-metallic, semiconducting, or non-conducting.

In an embodiment, the second component includes a phosphide, such as a phosphide of one of Ni or Ta.

In another embodiment, the second component includes a carbide, such as a carbide of one or more of Ti, Zr, Si, Zn, Nb, Ta, Al, Hf, Mn, Na, or B.

In yet another embodiment, the second component includes a silicide, such as a silicide of one or more of Sr, Ba, Ca, Ti, Zr, Ni, Fe, Y, Ta, Al, W, Mo, Ge, Mn, or V.

In still another embodiment, the second component includes a nitride, such as a nitride of one or more of B, Sr, Ba, Ca, Ti, Zr, Ni, Fe, Y, Ta, W, Mo, Ge, Mn, or V.

In various embodiments, the second component is present in an amount ranging from a second lower limit to a second upper limit, the second lower limit being one of 0%, 0.05%, 0.1%, 0.2%, and 0.5%, and the second upper limit being one of 1%, 1.5%, 2%, 2.5%, 3%, 4%, 5%, or 7.5%, the amount being measured by weight percentage of the paste composition.

### II. Organic Vehicle

The inorganic components of the present composition are typically mixed with an organic vehicle to form a relatively viscous material referred to as a “paste” or an “ink” that has a consistency and rheology that render it suitable for printing processes, including without limitation screen printing. The mixing is typically done with a mechanical system, and the constituents may be combined in any order, as long as they are uniformly dispersed and the final formulation has characteristics such that it can be successfully applied during end use.

A wide variety of inert materials can optionally be admixed in an organic medium in the present composition including, without limitation, an inert, non-aqueous liquid that optionally contains thickeners, binders, and/or stabilizers. By “inert” is meant a material that may be removed by a firing operation without leaving any substantial residue and that has no other effects detrimental to the paste or the final conductor line properties.

The proportions of organic vehicle and inorganic components in the present paste composition can vary in accordance with the method of applying the paste and the kind of organic vehicle used. In an embodiment, the present paste composition typically contains about 50 to 95 wt. %, 76 to 95 wt. %, or 85 to 95 wt. %, of the inorganic components and about 5 to 50 wt. %, 5 to 24 wt. %, or 5 to 15 wt. %, of the organic vehicle.

The organic vehicle typically provides a medium in which the inorganic components are dispersible with a good degree of stability of the chemical and functional properties of the paste composition. In particular, the composition preferably has a stability compatible not only with the requisite manufacturing, shipping, and storage, but also with conditions encountered during deposition, e.g., by a screen printing process. It is believed that in some embodiments, the inclusion of the additives provided herein enhances the stability of the present paste composition, e.g., against undesirable moisture pickup. Ideally, the rheological properties of the vehicle are such that it lends good application properties to the composition, including stable and uniform dispersion of solids, appropriate viscosity and thixotropy for printing, appropriate wettability of the paste solids and the substrate on which printing will occur, a rapid drying rate after deposition, and stable firing properties.

Substances useful in the formulation of the organic vehicle of the present paste composition include, without limitation, any one or more of the substances disclosed in U.S. Pat. No. 7,494,607 and International Patent Application Publication No. WO 2010/123967 A2, both of which are incorporated herein in their entirety for all purposes, by reference thereto. The disclosed substances include ethyl cellulose, ethylhydroxyethyl cellulose, wood rosin and derivatives thereof, mixtures of ethyl cellulose and phenolic resins, cellulose acetate, cellulose acetate butyrate, polymethacrylates of lower alcohols, monoalkyl ethers of ethylene glycol, monoacetate ester alcohols, and terpenes such as alpha- or beta-terpineol or mixtures thereof with other solvents such as kerosene, dibutylphthalate, butyl carbitol, butyl carbitol acetate, hexylene glycol, and high-boiling alcohols and alcohol esters. The organic vehicle may also include naturally-derived ingredients such as various plant-derived oils, saps, resins, or gums. Any of the polymers above or other suitable polymers may be present in the organic vehicle in any effective amount including, without limitation, an amount in the range of 0.1 wt. % to 5 wt. % of the total paste composition.

A preferred ester alcohol is the monoisobutyrate of 2,2,4-trimethyl-1,3-pentanediol, which is available commercially from Eastman Chemical (Kingsport, Tenn.) as TEXANOL™. Some embodiments may also incorporate volatile liquids in the organic vehicle to promote rapid hardening after application on the substrate. Various combinations of these and other solvents are formulated to provide the desired viscosity and volatility. The present paste composition may be adjusted as needed to a predetermined, screen-printable viscosity, e.g., by adding additional solvent(s).

In an embodiment, the organic vehicle may include one or more components selected from the group consisting of: bis(2-(2butoxyethoxy)ethyl) adipate, dibasic esters, octyl epoxy tallate, isotetradecanol, and a pentaerythritol ester of hydrogenated rosin. The paste compositions may also include additional additives or components.

The dibasic ester useful in the present paste composition may comprise one or more dimethyl esters selected from the group consisting of dimethyl ester of adipic acid, dimethyl ester of glutaric acid, and dimethyl ester of succinic acid. Various forms of such materials containing different proportions of the dimethyl esters are available under the DBE® trade name from Invista (Wilmington, Del.). For the present paste composition, a preferred version is sold as DBE-3 and is said by the manufacturer to contain 85 to 95 weight percent dimethyl adipate, 5 to 15 weight percent dimethyl glutarate, and 0 to 1.0 weight percent dimethyl succinate based on total weight of dibasic ester.

Further ingredients optionally may be incorporated in the organic vehicle, such as thickeners, stabilizers, and/or other common additives known to those skilled in the art. The organic vehicle may be a solution of one or more polymers in a solvent. Additionally, effective amounts of additives, such as surfactants or wetting agents, may be a part of the organic vehicle. Such added surfactant may be included in the organic vehicle in addition to any surfactant included as a coating on the conductive metal powder of the paste composition. Suitable wetting agents include phosphate esters and soya lecithin. Both inorganic and organic thixotropes may also be present.

Among the commonly used organic thixotropic agents are hydrogenated castor oil and derivatives thereof, but other suitable agents may be used instead of, or in addition to, these substances. It is, of course, not always necessary to incorporate a thixotropic agent since the solvent and resin properties coupled with the shear thinning inherent in any suspension may alone be suitable in this regard.

### III. Formation of Conductive Structures

### A. Substrate

An aspect of the disclosure provides a process that may be used to form a conductive structure on a substrate. Ordinarily, the process first entails the fabrication of a precursor structure of any desired configuration, generally comprising the steps of providing the substrate and applying a paste composition onto it in a suitable pattern. Then the applied paste composition and the substrate are fired to produce the conductive structure, which is often termed a “metallization.” Most commonly, the substrate is planar and relatively thin, thus defining opposing first and second major surfaces on its respective sides. The present paste composition may be used to form an electrode on one or both of these major surfaces.

### B. Insulating Layer

In some embodiments, the present paste composition is used in conjunction with a substrate, such as a semiconductor substrate, having an insulating or passivation layer present on one or more of the substrate's major surfaces. The layer may comprise, without limitation, one or more components selected from aluminum oxide, titanium oxide, silicon nitride,

SiNₓ:H (silicon nitride containing hydrogen for passivation during subsequent firing processing), silicon oxide, and silicon oxide/titanium oxide, and may be in the form of a single, homogeneous layer or multiple sequential sub-layers of any of these materials. Silicon nitride and SiNₓ:H are widely used. Passivation layers between 1 and 200 nm thick are suitable for typical applications.

In implementations for fabricating photovoltaic cells, the substrate ordinarily includes an insulating layer structured to provide an anti-reflective property, to lower the amount of incident light that is reflected from the cell's surface. Reducing the amount of light lost to reflection improves the cell's utilization of the incident light and increases the electrical current it can generate. Thus, the insulating layer is often denoted as an anti-reflective coating (ARC). The thickness of the layer preferably is chosen to maximize the anti-reflective property in accordance with the layer material's composition and refractive index. For example, the insulating ARC layer may have a thickness of between 1 and 200 nm. In one approach, the deposition processing conditions are adjusted to vary the stoichiometry of the layer, thereby altering properties such as the refractive index to a desired value. For a silicon nitride layer with a refractive index of about 1.9 to 2.0, a thickness of about 700 to 900 Å (70 to 90 nm) is suitable.

The insulating layer may be deposited on the substrate by methods known in the microelectronics art, such as any form of chemical vapor deposition (CVD) including plasma-enhanced CVD (PECVD) and thermal CVD, thermal oxidation, or sputtering. In another embodiment, the substrate is coated with a liquid material that under thermal treatment decomposes or reacts with the substrate to form the insulating layer. In still another embodiment, the substrate is thermally treated in the presence of an oxygen- or nitrogen-containing atmosphere to form an insulating layer. Alternatively, no insulating layer is specifically applied to the substrate, but a naturally forming substance, such as silicon oxide on a silicon wafer, may function as an insulating layer.

The present method optionally includes the step of forming the insulating layer on the semiconductor substrate prior to the application of the paste composition.

In some implementations of the present process, the paste composition is useful whether the insulating layer is specifically applied or naturally occurring. The paste's oxide and non-oxide components may act in concert to combine with, dissolve, or otherwise penetrate some or all of the thickness of any insulating layer material during firing.

### C. Application

The present composition can be applied as a paste onto a preselected portion of either major surface of the substrate in a variety of different configurations or patterns, depending on the device architecture and the particular substrate material used. The preselected portion may comprise any fraction of the total area of either of the major surfaces. The area covered may range from a small fraction up to substantially all of the area. In an embodiment, the paste is applied on a semiconductor substrate, which may be single-crystal, cast mono, multi-crystal, polycrystalline, or ribbon silicon, or any other semiconductor material.

The application can be accomplished using a variety of deposition processes, including screen printing and other exemplary deposition processes discussed above. In an embodiment, the paste composition may be applied over any insulating layer present on the pertinent major surface of the substrate.

The conductive composition may be printed in any useful pattern. For example, the application of the conductive paste may be used to form a photovoltaic cell precursor, wherein the paste is deposited on a preselected portion of a semiconductor substrate in a configuration that is appointed to be formed by a firing operation into an electrically conductive structure that includes at least one electrode in electrical contact with the substrate. In an implementation, the at least one electrode is configured to be connected to outside electrical circuitry to which electrical energy is to be supplied.

The electrode pattern used for a front side electrode of a photovoltaic cell commonly includes a plurality of narrow grid lines or fingers connected to one or more larger bus bars. Such a pattern permits the generated current to be extracted from the front side without undue resistive loss, while minimizing the area obscured by the metallization, which inherently reduces the amount of incoming light energy that can be converted to electrical energy. Ideally, the features of the electrode pattern should be well defined, with a preselected thickness and shape, and have high electrical conductivity and low contact resistance with the underlying structure. Fingers that are uniform and have a high ratio of height to width are beneficial in increasing the effective conductor cross sectional area (thus decreasing electrical resistance) while minimizing the obscured area. In an embodiment, the width of the lines of the conductive fingers may be 20 to 200 μm; 25 to 100 μm; or 35 to 75 μm. In an embodiment, the thickness of the lines of the conductive fingers may be 5 to 50 μm; 10 to 35 μm; or 15 to 30 μm.

Various embodiments of the present process are adapted to produce a photovoltaic cell precursor that comprises electrically separate first and second electrodes. For example, the preselected portion of the substrate may comprise separate first and second subportions located on the first major surface. The paste composition is applied to both the first and second subportions in an arrangement configured to be formed by the firing operation into the electrically conductive structure comprising the first and second electrodes in electrical contact with the first and second subportions, respectively. In an implementation, the first and second subportions consist essentially of p-type and n-type semiconductor material, respectively.

Another possible photovoltaic cell precursor configuration provides an electrically conductive structure comprising electrically separate first and second electrodes respectively located on the first and second major surfaces. The paste composition is applied onto preselected portions of the first and second major surfaces in an arrangement configured to be formed by the firing operation into the electrically conductive structure, with the first and second electrodes being in electrical contact with the preselected portions of the first and second major surfaces, respectively. In an implementation, the preselected portions of the first and second major surfaces consist essentially of p-type and n-type semiconductor material, respectively.

Any of the foregoing photovoltaic cell precursors can be fabricated into photovoltaic cell devices by the firing operation and resulting conversion of the deposited paste composition into a suitably configured conductive structure that provides electrodes in electrical communication with the semiconductor. It is to be understood that this firing operation ordinarily permits the electrode to penetrate any insulative layer on either or both major surfaces of the original substrate.

Photovoltaic architectures wherein no light is received on the back side can employ a back side electrode that provides one of the polarities and covers most or all that major surface. However, conductive structures with bus bar and finger configuration similar to that used as a front-side electrode can sometimes be employed on the back surface as well. Since there is no incident light that can be lost to shadowing, the dimensions of conductors in back side electrodes are generally not restricted by efficiency considerations. For example, wider conductive fingers may be used, and are in some instances beneficial in reducing the effective resistance of the back side electrode structure.

In still other architectures, a photovoltaic cell precursor may be configured to permit formation of electrodes of both polarities on the back surface, so that no light is lost because of front side obscuration. One such structure is the so-called “interdigitated back contact” or “IBC” configuration. US Patent Publication US2008-0230119, which is incorporated herein in its entirety for all purposes by reference thereto, discloses one possible form of an IBC configuration that is illustrated by its FIG. 1B. In some possible implementations of an IBC architecture, a silicon wafer is provided with alternating finger-like regions of n-type and p-type material located on the back surface. These regions can be prepared by a number of techniques wherein requisite dopants are provided on a wafer surface and allowed to diffuse (usually at elevated temperature) into the bulk of the wafer to form the respective regions of n-type and p-type material. The regions can be defined by processes such as printing or photolithography, with the dopants provided in liquid or gaseous form or by ion implantation or the like. Other methods for producing IBC cells are provided by U.S. Pat. No. 9,048,374 to Scardera et al., which is also incorporated herein in its entirety for all purposes by reference thereto.

Conductors formed by printing and firing a paste such as that provided herein are often denominated as “thick-film” conductors, since they are ordinarily substantially thicker than traces formed by atomistic processes, such as those used in fabricating integrated circuits. For example, thick-film conductors may have a thickness after firing of about 1 to 100 μm. Consequently, paste compositions that in their processed form provide conductivity and are suitably applied using printing processes are often called “thick-film pastes” or “conductive inks.”

### D. Firing

A heat treatment operation often termed “firing” may be used in the present process to promote the formation of a conductive structure that includes an electrode providing a high-quality electrical contact with an underlying substrate, such as a semiconductor wafer in a PV (photovoltaic) cell. A drying operation optionally precedes the firing operation, and is carried out at a modest temperature to harden the paste composition by removing its most volatile organics.

The firing operation is believed to effect a substantially complete burnout of the organic vehicle from the deposited paste by volatilization and/or pyrolysis of the organic materials. While the present invention is not limited by any particular theory of operation, it is believed that during firing, the first oxide-containing component and the second component (if present) act in concert to efficiently penetrate the insulating layer normally present on the wafer, such as a naturally-occurring or intentionally formed passivation layer and/or an antireflective coating. Such a result is frequently termed “firing through.” The various paste components are also thought to promote sintering of the conductive metal powder, e.g. silver, that forms the electrode.

Ideally, the firing results in formation of an electrode that has good electrical properties, including a high bulk conductivity and a low surface resistivity connection to the underlying semiconductor material, thereby reducing the source impedance of the cell. While some embodiments may function with electrical contact that is limited to conductive domains dispersed over the printed area, it is preferred that the contact be uniform over substantially the entire printed area. It is also beneficial for the conductive metal structure to be mechanically robust and securely attached to the substrate, with a metallurgical bond being formed over substantially all the area of the substrate covered by the conductive element.

In an embodiment, the conductive metal is separated from the silicon by a nanometer-scale interfacial film layer (typically of order 5 nm or less) through which the photoelectrons tunnel. In another embodiment, contact is made between the conductive metal and the silicon by a combination of direct metal-to-silicon contact and tunneling through thin interfacial film layers.

In one embodiment, the temperature for the firing may be in the range between about 300° C. and about 1000° C., or about 300° C. and about 525° C., or about 300° C. and about 650° C., or about 650° C. and about 1000° C. The firing may be conducted using any suitable heat source, and may be performed in an atmosphere composed of air, nitrogen, an inert gas, or an oxygen-containing mixture such as a mixed gas of oxygen and nitrogen. In an embodiment, the firing is accomplished by passing the substrate bearing the printed paste composition pattern through a belt furnace at high transport rates, for example between about 100 to about 500 cm per minute, with resulting hold-up times between about 0.05 to about 5 minutes. Multiple temperature zones may be used to control the desired thermal profile in the furnace, and the number of zones may vary, for example, between 3 to 11 zones. The temperature of a firing operation conducted using a belt furnace is conventionally specified by the furnace set point in the hottest zone of the furnace, but it is known that the peak temperature attained by the passing substrate in such a process is somewhat lower than the highest set point. Other batch and continuous rapid fire furnace designs known to one of skill in the art are also contemplated.

In various process embodiments, the paste composition is applied to a preselected portion of the substrate that consists essentially of either n-doped or p-doped semiconducting material. The skilled person will recognize that, ideally, confining the metallization to material that is entirely of the desired conductivity type precludes electrical shunting, but that some overlap onto undoped regions of a substrate will not appreciably degrade the electrical quality of the connection, as long as the metallization does not bridge from an n-doped region to a p-doped region.

The present paste composition is readily used to fabricate electrodes that contact regions of a planar semiconductor surface that are doped to render them either n-type or p-type. For example, the composition may be used to contact the p-type emitter region of an n-type base cell or a p-type base region. The composition may be used to contact n-type regions, provided the semiconductor does not include a p-n junction that is shunted by the fabrication. In some embodiments, the same composition may be used to form electrodes on regions of both conductivity types. The various materials may be applied and then co-fired, or they may be applied and fired sequentially.

The preselected portion is ordinarily, but not required to be, on a major surface of a thin semiconductor wafer. A conductive structure, such as an electrode, is formed on the substrate by depositing and firing the paste, whereby the conductive structure is prepared and configured to be connected to an external electric load for the transfer of conduction electrons to or from the semiconductor, so that the semiconductor device can function in its intended manner as a circuit element. For example, a photovoltaic cell thus functions as an energy source by converting incident light into electrical energy that can do useful work.

In many conventional photovoltaic cell architectures, the n-doped and p-doped regions are located on opposite major sides of a thin semiconductor wafer. Frequently, the doped regions comprise all, or nearly all, the area of the respective major surfaces. It is surprising and unexpected that the present paste composition can be used to fabricate electrodes contacting both n-doped and p-doped regions. Consequently, it can be used for making front-side electrodes of both conventional p-base cells and the less common n-base cells, in which the front-surface emitters are respectively n-doped and p-doped, with other known paste compositions being used to form respective rear-surface base electrodes with the correspondingly opposite polarity and doping type.

Alternatively, certain embodiments of the paste composition are also useful in processes wherein the same composition is used to fabricate the electrodes for both the emitter and base regions. For example, cells may have either an n-doped or p-doped region on the front major surface of a thin wafer substrate, with a correspondingly opposite doping type on the opposite rear major surface, with the same paste being used for both surfaces.

In a further embodiment, the present paste composition may be employed in the construction of semiconductor devices wherein both p- and n-doped regions are situated on a single surface of a substrate, instead of being on opposing major surfaces of the substrate. In one possible implementation of such a configuration, the respective n-doped and p-doped regions encompass areas that are side-by-side on the non-illuminated (back) side of a photovoltaic device, thereby eliminating front-side shadowing and improving utilization of the incident light. In this or like configurations, the electrodes are formed on preselected portions that are each ideally confined to a region having one of the doping types to preclude electrical shunting,

### E. Semiconductor Device Manufacture

An embodiment of the present disclosure relates to a device structure comprising a substrate and a conductive electrode, which may be formed by the process described above.

Conductive structures as provided herein may be usefully employed in a wide range of electrical, electronic, and semiconductor devices. Without limitation, such devices include photodiodes, photovoltaic cells, and solar panels or other like articles, in which one or more conductive structures function as electrodes through which the device can be connected to other electrical circuitry. Devices that are individually or collectively fabricated using processes disclosed herein may be incorporated into larger structures, such as a solar panel including a plurality of interconnected photovoltaic cells.

Certain embodiments of the present paste composition are useful in fabricating electrodes on semiconductor wafers with a range of concentrations and profiles of both n- and p-type dopants, including ones in which an insulating layer, such as a silicon nitride layer present on a major surface of the substrate, must be penetrated to establish contact.

As known to one skilled in the art (see, e.g., S. W. Jones, “Diffusion in Silicon,” IC Knowledge LLC (2008), pp. 56-62), dopant concentration is typically measured using a SIMS (secondary ion mass spectrometry) depth profiling method; active dopant concentration is measured using SRP (spreading resistance probing) or ECV (electrochemical capacitance voltage) methods.

One common class of Si solar cell designs employs a 200 μm thick p-type Si wafer with a 0.4 μm emitter layer of n-type Si produced by phosphorus (P) doping on the wafer's front surface. In various implementations the n-type layer is made by either diffusing or ion implanting P dopant into the Si wafer. Without being bound by any theory, it is commonly assumed that for such p-base cells, a high P dopant concentration in the n-type emitter tends to decrease emitter sheet resistivity and to enable a low resistivity metal contact to be made at the Si surface, thereby decreasing resistance losses. However, it is further understood that a high dopant concentration introduces crystalline defects or electrical perturbations in the Si lattice that increase recombination losses, which tend to reduce both the current and voltage capability of a finished cell.

Conventional p-base photovoltaic cells are commonly prepared with n-type emitters that have a total concentration of P dopant at the front surface (“[P_{surface}]”) that ranges from 9 to 15×10²⁰ atoms/cm³. The active [P_{surface}] typically ranges from 3 to 4×10²⁰ atoms/cm³. Such emitters are denominated as highly or heavily doped emitters (HDE). Wafers incorporating those emitters are often referenced simply as “HDE wafers.”

A value of [P_{surface}] above ˜1×10²⁰ atoms/cm³ in Si is believed to lead to various modes of recombination. Recombined charge carriers are bound to the Si lattice and unable to be collected to provide usable electrical energy. The solar cell energy loss is manifested in a decrease of both Voc (open circuit voltage) and Isc (short circuit current). P dopant in excess of the active concentration (inactive P) leads to Shockley-Read-Hall (SRH) recombination energy loss. An active P dopant level above ˜1×10²⁰ atoms/cm³ is thought to lead to Auger recombination energy loss. As a result, HDE wafers used for commercial solar cells may exhibit a degraded response to short wavelength light, which typically have a very high absorption coefficient in silicon and are absorbed very close to the surface.

On the other hand, emitters can be made with a lower dopant concentration at the wafer surface. A wafer having a lightly or low-doped emitter with [P_{surface}]<1×10²⁰ atoms/cm³ is typically termed an LDE wafer. It is believed that solar cell embodiments employing lightly doped emitters can potentially achieve improved solar cell performance by decreasing the losses resulting from electron-hole recombination at the front surface. However, a lower surface dopant concentration is also frequently understood to make it more difficult to establish a low-resistance connection to the underlying semiconductor. Thus, the inherent potential of LDE-based cells to provide improved cell performance is frequently mitigated in practice, since low resistance contact is needed for efficient extraction of current from the operating cell. Overcoming these limitations requires a paste composition capable of forming electrodes that can reliably contact lightly doped, low [P_{surface}] emitters without damaging the emitter layer surface, while still providing low contact resistance.

Ideally, such a paste would enable screen-printed crystalline silicon solar cells to have reduced saturation current density at the front surface (J0e) and accompanying increased Voc and Jsc, and therefore improved solar cell performance. Other desirable characteristics of a paste would include high bulk conductivity and the ability to form narrow, high-aspect-ratio contact lines in a metallization pattern to further reduce series resistance and minimize shading of incident light by the electrodes, as well as good adherence to the substrate.

One possible sequence of steps implementing the present process for manufacture of a photovoltaic cell device is depicted by FIGS. 1A-1F. While the process is described with reference to a conventional p-base cell having a planar architecture, comparable steps useful in fabricating planar n-base cells or cells having other architectures such as interdigitated back contact cells will also be apparent.

FIG. 1A shows a p-type substrate 10, which may be single-crystal, multi-crystalline, or polycrystalline silicon. For example, substrate 10 may be obtained by slicing a thin layer from an ingot that has been formed from a pulling or casting process. In an implementation, the Si ingot is doped with B to render it p-type. Surface damage and contamination (from slicing with a wire saw, for example) may be removed by etching away about 10 to 20 μm of the substrate surface using an aqueous alkali solution such as aqueous potassium hydroxide or aqueous sodium hydroxide, or using a mixture of hydrofluoric acid and nitric acid. In addition, the substrate may be washed with a mixture of hydrochloric acid and optional hydrogen peroxide to remove heavy metals such as iron adhering to the substrate surface. Although not specifically depicted, substrate 10 may have a first major surface 12 that is textured to reduce light reflection. Texturing may be produced by etching a major surface with an aqueous alkali solution such as aqueous potassium hydroxide or aqueous sodium hydroxide. Substrate 10 may also be formed from a silicon ribbon.

In FIG. 1B, an n-type diffusion layer 20 is formed to create a p-n junction with p-type material below. The n-type diffusion layer 20 can be formed by any suitable doping process, such as thermal diffusion of phosphorus (P) provided from phosphorus oxychloride (POCl₃) or ion implantation. As shown, the n-type diffusion layer 20 is formed over the entire surface of the silicon p-type substrate. In other implementations, the diffusion layer is confined to the top major surface, obviating the need for the removal process. The depth of the diffusion layer can be varied by controlling the diffusion temperature and time, and is generally formed in a thickness range of about 0.3 to 0.5 μm. The n-type diffusion layer may have a sheet resistivity from several tens of ohms per square up to about 120 ohms per square. In some alternative implementations (not shown), additional doping with B at a level above that of the bulk is added in a layer on second (rear) major surface 14.

After protecting one surface of the n-type diffusion layer 20 with a resist or the like, the n-type diffusion layer 20 is removed from most surfaces by etching so that it remains only on the first major surface 12 of substrate 10, as shown in FIG. 1C. The resist is then removed using an organic solvent or the like.

Next, as shown in FIG. 1D, an insulating layer 30, which also functions as an anti-reflective coating, is formed on the n-type diffusion layer 20. The insulating layer is commonly silicon nitride, but can also be a layer of another material, such as SiNₓ:H (i.e., the insulating layer comprises hydrogen for passivation during subsequent firing processing), titanium oxide, silicon oxide, mixed silicon oxide/titanium oxide, or aluminum oxide. The insulating layer can be in the form of a single layer or multiple layers of the same or different materials.

Next, electrodes are formed on both major surfaces 12 and 14 of the substrate. As shown in FIG. 1E, a paste composition 90 as provided herein is screen printed on the insulating layer 30 of the first major surface 12 and then dried. For a photovoltaic cell, paste composition 90 is typically applied in a predetermined pattern of conductive lines extending perpendicularly from one or more bus bars that occupy a predetermined portion of the surface. In addition, aluminum paste 60 and back-side silver paste 70 are screen printed onto the back side (the second major surface 14 of the substrate) and successively dried. The screen printing operations may be carried out in any order. For the sake of production efficiency, all these pastes are typically processed by co-firing them, typically at a temperature in the range of about 700° C. to about 975° C. for a period of from several seconds to several tens of minutes in air or an oxygen-containing atmosphere. An infrared-heated belt furnace is conveniently used for high throughput.

As shown in FIG. 1F, the firing causes the depicted paste composition 90 on the front side to sinter and penetrate through the insulating layer 30, thereby achieving electrical contact with the n-type diffusion layer 20, a condition known as “fire through.” This fired-through state, i.e., the extent to which the paste reacts with and passes through the insulating layer 30, depends on the quality and thickness of the insulating layer 30, the composition of the paste, and on the firing conditions. A high-quality fired-through state is believed to be an important factor in obtaining high conversion efficiency in a photovoltaic cell. Firing thus converts paste 90 into electrode 91, as shown in FIG. 1F.

The firing further causes aluminum to diffuse from the back-side aluminum paste 60 into the silicon substrate, thereby forming a p+ layer 40, containing a high concentration of aluminum dopant. This layer is generally called the back surface field (BSF) layer, and helps to improve the energy conversion efficiency of the solar cell. Firing converts the dried aluminum paste 60 to an aluminum back electrode 61. The back-side silver paste 70 is fired at the same time, becoming a silver or silver/aluminum back electrode 71. It is believed that during firing, the boundary between the back-side aluminum and the back-side silver assumes the state of an alloy, thereby achieving electrical connection. Most areas of the back electrode are occupied by the aluminum electrode, owing in part to the need to form a p+ layer 40. Since there is no need for incoming light to penetrate the back side, substantially the entire surface may be covered. At the same time, because soldering to an aluminum electrode is unfeasible, silver or silver/aluminum back electrode 71 is formed on the back side as an electrode to permit soldered attachment of interconnecting copper ribbons or the like. Although silver paste 70 is depicted as covering the same area as aluminum paste 60, it is sufficient for electrode 71 to cover a limited area that still accommodates this solder attachment.

It will be understood that the present paste composition and process may also be used to form electrodes, including a front-side electrode, of a photovoltaic cell in which the p- and n-type layers are reversed from the construction shown in FIGS. 1A-1F, so that the substrate is n-type and a p-type material is formed on the front side.

Another embodiment of the present device and the process used for its fabrication are depicted by FIGS. 2A-2F, which depict the preparation of a photovoltaic cell having bus bar/finger electrodes on both major surfaces.

FIG. 2A shows a part of an N-type base Si semiconductor substrate 110 with a p-type emitter 120. N-base substrate 110 can be formed by slicing a Si wafer from a starting ingot and doping it with a donor impurity such as P. The doping can be done either during ingot production or after the slicing operation. The p-type emitter 120 can be formed, for example, by thermal diffusion of an acceptor dopant into the sliced Si wafer. For example, the acceptor dopant can be provided from a boron compound such as boron tribromide (BBr₃). The thickness of the p-type emitter can be, for example, 0.1 to 10% of the N-type base semiconductor substrate thickness.

As shown in FIG. 2B, a passivation layer 130a can be formed on the p-type emitter 120. The passivation layer can be 1 to 200 nm thick and comprise silicon nitride, SiNₓ:H, silicon carbide (SiCₓ), titanium oxide (TiO₂), aluminum oxide (Al₂O₃), silicon oxide (SiOₓ), indium tin oxide (ITO), or a mixture thereof. The passivation layer can be formed by, for example, plasma enhanced chemical vapor deposition (PECVD) of these materials. In operation of a photovoltaic cell with the configuration shown, sunlight is incident on passivation layer 130a, which thus functions as an anti-reflective coating (ARC) as explained above. Layer 130a also acts to reduce carrier recombination.

In an embodiment, as shown in FIG. 2C, an n⁺-layer 140 is optionally formed on the major surface of substrate 110 opposite p-type emitter 120. If present, the n⁺-layer 140 contains the donor impurity with a higher concentration than in the bulk of n-base substrate 110. For example, the n⁺-layer 140 can be formed by thermal diffusion of phosphorus in the case of a silicon semiconductor. Inclusion of n⁺-layer 140 is believed to reduce the recombination of electrons and holes at the interface between n-base layer 110 and n⁺-layer 140.

As shown in FIG. 2D, a passivation layer 130b is formed on n⁺-layer 140 using the same materials and techniques employed for passivation layer 130a. Alternatively, different materials and/or processing may be used.

As shown in FIG. 2E, conductive paste 160 for forming a p-type electrode is applied onto the passivation layer 130a on the p-type emitter 120. A conductive paste 170 for forming an n-type electrode is applied onto the passivation layer 130b on n⁺-layer 140. Both conductive pastes are typically applied by screen printing techniques.

In an embodiment, the conductive paste 170 on the n⁺-base layer 140 is different in composition from the conductive paste 160 on the p-type emitter 120. The composition of the conductive paste 170 can be adjusted depending on, for example, the material or thickness of the passivation layer.

In another embodiment, the same material is used for both conductive paste 160 and conductive paste 170. Use of the same composition for both deposits may simplify the manufacturing process and thereby reduce production costs.

After deposition, conductive pastes 160 and 170 are optionally dried, e.g., for 10 seconds to 10 minutes at 150° C.

Thereafter, the structure and the deposited conductive pastes are fired. As shown FIG. 2F, the conductive pastes 160 and 170 penetrate, or fire through, their respective passivation layers 130a, 130b so that p-type electrode 161 and n-type electrode 171 are formed and make electrical connections with p-type emitter 120 and n⁺-layer 140 respectively. Low resistance connections between these electrodes and the underlying semiconductor are needed for efficient extraction of electrical energy from the photovoltaic cell. Ideally, the attachment of the electrodes is also tenacious and mechanically robust.

A semiconductor device fabricated as described above may be incorporated into a photovoltaic cell. In another embodiment, a photovoltaic cell array includes a plurality of the aforementioned semiconductor devices as described. The devices of the array may be made using a process described herein.

It will be apparent that similar processes can be used to fabricate conductive structures in photovoltaic cells having other architectures or other electrical, electronic, and semiconductor devices, all of which are contemplated within the scope of the present disclosure.

### EXAMPLES

The operation and effects of certain embodiments of the present invention may be more fully appreciated from a series of examples (Examples 1-50) described below. The embodiments on which these examples are based are representative only, and the selection of those embodiments to illustrate aspects of the invention does not indicate that materials, components, reactants, conditions, techniques and/or configurations not described in the examples are not suitable for use herein, or that subject matter not described in the examples is excluded from the scope of the appended claims and equivalents thereof.

### Materials

Materials used in preparing the paste compositions and photovoltaic cells in the examples herein and commercial sources are set forth below:

### Oxides

CsVO₃ from Alfa Aesar;
Li₂CO₃, Na₂CO₃, K₂CO₃, Rb₂CO₃, and Cs₂CO₃ from Aldrich;
K₂CO₃ from JMC-Puratronic;
B₂O₃ and TiO₂ (anatase) from Alfa Aesar;
Al₂O₃ from ICN Alumina;
V₂O₅ and SiO₂ from Aldrich; and
ZnO from US Zinc Corp.;

Li₂RuO₃ was synthesized using techniques described in U.S. Pat. No. 8,808,581, which is hereby incorporated in its entirety for all purposes by reference thereto;

### Non-Oxides

SiC, TiN, ZrN, and Mg₂Si from Alfa Aesar;
TiC, HfC, Ni₂P, and TaP from Cerac;
Nano-TiC from Aldrich (represented by the manufacturer as being nanopowder, <200 nm particle size by TEM);
VC from Aldrich;
Zn metal from Umicore; and
BN (hexagonal) from the Carborundum Company.

### Oxide Component Preparation

The oxide components used in the present conductive paste can be prepared using any suitable technique, including ones generally employed in the glass-making arts. Generally stated, the oxides used in the following paste preparations were prepared by blending the requisite solid oxides or other suitable precursors (e.g., carbonates). The blend was then heated in a Pt crucible and held at a temperature sufficient to melt the constituents together, and thereafter poured onto a stainless steel quench plate. The solidified mass was ground to coarse powder and then ball milled to attain a desired small particle size, such as a d₉₀ (measured using a Horiba LA-910 analyzer) of 2-3 μm. Typically, the milling was carried out in a polyethylene container with zirconia media and isopropyl alcohol or water optionally containing 0.5 wt. % TRITONTM X-100 octylphenol ethoxylate surfactant (available from Dow Chemical Company, Midland, Mich.). The comminuted powder was recovered by centrifugation or filtration and then dried.

### Silver Powder

The Ag powder used in the exemplary paste compositions below was finely divided and represented by the manufacturer as having a predominantly spherical shape. It was determined to have a particle size distribution with a d₅₀ of about 2.3 μm (as measured in an isopropyl alcohol dispersion using a Horiba LA-910 analyzer).

### Organic Vehicle

Generally stated, the paste compositions below were formulated by dispersing the constituent inorganic solids in an organic vehicle, which was prepared as a masterbatch using a planetary, centrifugal Thinky® mixer (available from Thinky® USA, Inc., Laguna Hills, Calif.) to mix the ingredients listed in Table I below, with percentages given by weight. TEXANOL™ ester alcohol solvent is available from Eastman Chemical Company, Kingsport, Tenn. A small percentage of the nominal solvent content was typically held back to permit later viscosity adjustment, as further described below.

TABLE I
Organic Vehicle Composition

| Ingredient | wt. % |
|---|---|
| 11% ethyl cellulose (50-52% ethoxyl) dissolved | 8.43% |
| in TEXANOL ™ solvent | |
| 8% ethyl cellulose (48-50% ethoxyl) dissolved in | 8.43% |
| TEXANOL ™ solvent | |
| tallowpropylenediaminedioleate | 5.69% |
| pentaerythritol ester of hydrogenated rosin | 29.61% |
| gum damar | 4.27% |
| hydrogenated castor oil derivative | 5.69% |
| dibasic ester | 29.61% |
| aromatic solvent | 1.42% |
| TEXANOL ™ solvent | (balance) |

### Paste Preparation

Generally stated, the paste compositions herein were prepared by combining the requisite amounts of the first, oxide-containing component and Ag powder in a glass jar and tumble-mixing them for about 15 min. This mixture was added by thirds to a jar containing organic vehicle from the aforementioned masterbatch and mixed after each addition using the aforementioned Thinky® mixer for 1 minute at 2000 RPM, whereby the ingredients were well dispersed in the organic vehicle.

After the final addition, the paste was cooled and the viscosity was adjusted to between about 300 and 400 Pa·s by adding solvent and Thinky mixing for 1 minute at 2000 RPM. The paste was then milled on a three-roll mill (Charles Ross and Son, Hauppauge, N.Y.) with a 25 μm gap for 3 passes at zero pressure and 3 passes at 100 psi (689 kPa).

Each paste composition was allowed to sit for at least 16 hours after roll milling, and then its viscosity was adjusted to ˜300 Pa·s with additional TEXANOL™ solvent to render it suitable for screen printing. The viscometer was a Brookfield viscometer (Brookfield Inc., Middleboro, Mass.) with a #14 spindle and a #6 cup. Viscosity values were taken after 3 minutes at 10 RPM. Typically, a viscosity of about 300 Pa·s has been found to yield good screen printing results, but some variation, for example ±50 Pa·s or more, would be acceptable, depending on the precise printing parameters.

The foregoing process was determined to produce paste composition material that was sufficiently homogenous to achieve reproducible solar cell performance.

Some of the paste compositions described herein further comprise one or more discrete additive substances along with the alkali metal vanadium oxide composition. In various embodiments, the additives included an oxide material that is considered as part of the first, oxide component and/or a second, non-oxide, non-metal component.

As indicated below, paste compositions containing such additives were made using two alternative protocols. For some compositions, a paste masterbatch containing conductive metal powder, the alkali vanadium oxide composition, and the preformulated organic vehicle was first mixed and roll milled as described above. Then the additive was added separately to the masterbatch and another mixing operation was carried out in the Thinky® mixer for 3 cycles of 1-2 min. each, with a period of cooling between steps to assure the effectiveness of the mixing.

For other compositions, the additive substances were first sieved to −325 mesh and then dry-mixed with the alkali vanadium oxide composition and conductive metal powder. The combined inorganics were then mixed in aliquots with the organic vehicle in the aforementioned Thinky® mixer and thereafter roll milled, as described generally above.

The viscosity of each finished paste after either mixing protocol was adjusted as needed to a value suitable for screen printing by adding a small amount of TEXANOL™ solvent. It is to be understood that in the examples below, the amounts of the ingredients listed are nominal amounts, which may not add up to exactly 100%. In accordance with conventional practice, provision is made for the aforementioned viscosity adjustment by holding back a small amount of the solvent (typically 2 to 3% by total weight). In some instances, addition of the entire holdback is not required to attain the desired final viscosity.

### Si Wafer Substrates

The photovoltaic cells of the examples below were prepared on crystalline Si substrates of various types. For convenience, the experiments were all carried out using ˜28 mm×28 mm “cut down” wafers prepared by dicing large starting wafers (e.g. ˜156 mm×156 mm square wafers, ˜200 μm thick) with a diamond blade saw, unless otherwise indicated. Performance of such 28 mm×28 mm cells is known to be impacted by edge effects, which typically reduce the overall photovoltaic cell efficiency by as much as ˜1 to 3% from what would be obtained with full-size wafers. A conventionally applied SiNₓ:H antireflective coating (ARC) was present on both major surfaces of the N-type wafers and on just the front (sun-facing) major surface of the P-type wafers.

### N-Type:

Monocrystalline wafers with a phosphorus-doped, n-type base and a relatively heavily boron-doped front layer that forms a surface p-type emitter region having a 70-75 Ω/sq. surface resistivity were used for some of the examples. The wafers were obtained from the International Solar Energy Research Center, Konstanz, Germany. A diffusion process was also used to increase the P dopant level in a back surface layer to create a back surface field (BSF) and thereby reduce surface recombination and enhance cell efficiency. Both major surfaces were textured to enhance light trapping, but with different texture topographies on the front and back surfaces.

### P-Type:

Several p-type Si wafers that differ in the doping in their front surface, n-type emitter regions were used in the other examples reported below. As set forth above, both the overall doping profile and the surface dopant concentration are understood to influence the overall quality of photovoltaic cells fabricated using these wafers. Since both a high recombination loss and a high resistance electrical connection are deleterious to the overall electrical performance of a PV cell, different approaches have been taken to balance these factors, as is implicit in the various p-type wafer substrates described below: The p-type wafers herein were all textured on both major surfaces by a hydroxide etching treatment.

HDE: multicrystalline wafers having a boron-doped, p-type base and a highly phosphorus-doped emitter yielding a 65 Ω/sq. surface resistivity, obtained from Gintech Energy Corporation, Jhunan Township, Taiwan.

LDE: monocrystalline wafers (obtained from DuPont Sunnyvale Technology Center, Sunnyvale, Calif.) having a boron-doped, p-type base and a lightly phosphorus-doped emitter, yielding about 65-80 Ω/sq. surface resistivity. These wafers feature a surface P concentration about 50% lower than that of typical HDE wafers. The SiNₓ:H ARC was present only on the anisotropically textured front surface. It is believed that the lower doping reduces recombination losses in LDE based photovoltaic cells but makes it more difficult to establish good electrical contact between the metallization and the wafer with known Ag-based paste compositions.

### Conductive Paste Compositions

Back side electrodes of the exemplary photovoltaic cells below were prepared using aluminum-containing paste compositions that are available commercially under the trade names SOLAMET® PV35A and SOLAMET® PV35C from E.I. du Pont de Nemours and Co., Wilmington, Del.

### Cell Fabrication

Generally stated, electrodes for the exemplary photovoltaic cells below were formed by screen printing the desired paste composition in a preselected pattern onto the opposing major sides of a thin silicon wafer, using a screen printer, such as an AMI-Presco (AMI, North Branch, N.J.) MSP-485 semi-automatic screen printer. The front-side electrodes were formed in a comb-like pattern comprising 13 fingers (pitch ˜0.20 cm) extending perpendicularly from a bus bar (hereinafter, “bus bar/finger” configuration). Some of the back-side electrodes were made in a similar configuration, but with a printing screen that produced slightly wider finger conductors. The back side metallization for other cells was formed by screen printing a 27.5 mm×27.5 mm square pattern of a suitable Al-containing paste that produces a full-plane Al—Si eutectic back contact upon firing.

After printing and drying, the cells were fired in a rapid thermal processing, multi-zone belt furnace (BTU International, North Billerica, Mass.). For each paste, at least 9 cells were printed, so that 3 cells could be fired at each of at least 3 laddered furnace peak set point temperatures. It is understood that the peak temperature experienced by each cell during passage through the firing furnace in such a process is about 140 to 150° C. lower than the peak zone temperature. After firing, the median conductor line width for the front side electrodes was ˜80-100 μm and the mean line height was ˜10-15 μm. The bus bar was 1.25 mm wide. The median line resistivity was ˜2.2-2.7 μΩ-cm. For back-side electrodes in the bus bar/finger configuration, the median line width for the finger conductors was ˜210-220 μm.

For each example, an optimum firing temperature was identified as the temperature that resulted in the highest mean or median efficiency, based on the 3-cell test groups for each paste composition and temperature.

### Electrical Testing

Unless otherwise specified, electrical properties reported herein were measured using an ST-1000 IV tester (Telecom STV Co., Moscow, Russia). The Xe arc lamp in the IV tester simulates sunlight with a known intensity and irradiates the front surface of the cell. Tests were carried out on photovoltaic cells at 25±1.0° C. with a light intensity of 1.0 Sun. The tester uses a four contact method to measure current (I) and voltage (V) at approximately 400 load resistance settings to determine the cell's I-V curve. Efficiency (Eff), fill factor (FF), and apparent series resistance (Rₐ) were obtained from the I-V curve for each cell. Rₐ is defined in a conventional manner as the negative of the reciprocal of the local slope of the IV curve near the open circuit voltage. As recognized by a person of ordinary skill, Rₐ is conveniently determined and a close approximation for Rₛ, the true series resistance of the cell. Open circuit voltage (V_{oc}) was measured in a conventional manner for some of the cells.

Tests were carried out after the firing of the photovoltaic cells. For each combination of pastes and wafer type, an optimum firing temperature was identified as the temperature that resulted in the highest mean or median efficiency, based on a 3-cell test group. Mean or median electrical results are reported for the cell groups fired at the optimal firing temperature thus determined. For each furnace condition and run cycle, control cells were made with known commercial wafer samples and conductive pastes. The control cells were included in each firing and thereafter tested. The processing and electrical testing were assumed valid as long as the results for the control cells were within established limits. Of course, the foregoing protocols are exemplary and other equipment and procedures suitable for heat treating and testing efficiencies and other pertinent electrical properties will be recognized by one of ordinary skill in the art.

### Examples 1a to 4a

### Preparation of Conductive Paste Compositions Containing Cesium Metavanadate

### Paste Preparation

Several conductive paste compositions containing various amounts of the stoichiometric crystalline compound, cesium metavanadate (CsVO₃), Ag powder, and organic vehicle were prepared. The CsVO₃ was either obtained directly or synthesized by melting together Cs₂CO₃ and V₂O₅ as described above. Similar results were obtained for either form of CsVO₃. The Ag powder and organic vehicle were as described above. The resulting paste composition was used to fabricate front-side electrodes on crystalline Si photovoltaic cells.

The nominal CsVO₃ content of the paste compositions of Examples 1a to 4a is set forth in Table II. The final paste compositions contained CsVO₃, about 86 to 87% Ag, and about 9 to 10% organic vehicle, by weight of the total paste composition, and were prepared in the manner described above.

TABLE II
Cesium Metavanadate Content in Conductive Paste Compositions

| Example | wt. % CsVO₃ |
|---|---|
| 1a | 1.0% |
| 2a | 1.3% |
| 3a | 1.6% |
| 4a | 1.8% |

### Examples 1 b to 4b

### Fabrication and Testing of N-Type Photovoltaic Cells Using Cesium Metavanadate-Containing Conductive Paste

### Cell Fabrication

Photovoltaic cells were fabricated on 28 mm×28 mm cut-down, n-type wafers using the paste compositions of Examples la to 4a to fabricate front-side electrodes for the cells of Examples 1b to 4b, respectively, and PV17F paste to fabricate back side electrodes. Both electrodes were formed with the aforementioned bus bar/finger configuration. PV17F paste is known to permit good electrical contact to be established on phosphorus-doped, n-type regions of Si wafers. The cells were fired at peak temperature set points of 875, 900, and 925° C.

### Electrical Testing

Electrical properties of the photovoltaic cells thus fabricated were measured as set forth above, yielding the results provided in Table III.

TABLE III
Electrical Properties of N-type Monocrystalline Solar Cells

| | wt. % CsVO₃ | Eff. | FF | Ra |
|---|---|---|---|---|
| Example | in paste | (%) | (%) | (Ω) |
| 1b | 1.0 | 16.4 | 69.2 | 0.23 |
| 2b | 1.3 | 16.7 | 70.6 | 0.21 |
| 3b | 1.6 | 16.4 | 70.1 | 0.22 |
| 4b | 1.8 | 16.4 | 71.0 | 0.21 |

These experiments demonstrate that the present paste compositions, formulated with a CsVO₃ oxide component and Ag as the conductive metal, can be used successfully to fabricate electrodes contacting a p-type, boron-doped emitter regions of n-base photovoltaic cells. The exemplary cells have attractive electrical properties, which are comparable to those obtained with cells wherein a conventional Al-containing paste is used to fabricate the electrodes for the p-type emitter region.

It is notable that the pastes used in Example 1b-4b contain no metallic Al. These examples demonstrate that inclusion of Al in the form of metallic Al powder is not necessary to establish satisfactory electrical contact with boron-doped emitters and achieve acceptable cell efficiency in n-type solar cells, contrary to the conventional understanding in the prior art.

### Example 5a

### Preparation of Conductive Paste Compositions Containing Cesium Metavanadate

A paste composition was prepared using the same composition, constituents (including 1.8 wt. % CsVO₃), and processing as set forth above for Example 4a.

### Example 5b

### Fabrication and Testing of Photovoltaic Cells on P-Type HDE Wafers

The photovoltaic cells of Example 5b were prepared using the paste compositions of Example 5a and PV35A to form bus bar/finger front-side and full-coverage back side electrodes, respectively, on p-type HDE wafers. Electrical test results for these cells after firing are shown in Table IV.

TABLE IV
Electrical Properties of P-Type HDE Multicrystalline Si Solar Cells

| | Eff. | FF | Ra |
|---|---|---|---|
| Example | (%) | (%) | (Ω) |
| 5b | 15.93 | 77.8 | 0.163 |

The results of Examples 1-5 together demonstrate that pastes containing a CsVO₃-based oxide component and Ag powder as the conductive metal can be used to fabricate bus bar/finger configuration front-surface electrodes on both n-type and p-type photovoltaic cells, and that high conversion efficiencies are obtainable in both types.

### Examples 6a-7a

### Preparation of Conductive Paste Compositions Containing Cesium Metavanadate

Paste compositions having the same composition as in Examples 4a and 5a were prepared as Examples 6a and 7a, using the same constituents and processing set forth above. The Example 6a paste was prepared using the commercially-sourced CsVO₃ listed above, while the Example 7a paste was made with CsVO₃ synthesized in the lab by melting together CsCO₃ and V₂O₅.

### Examples 6b-7b

### Fabrication and Testing of Photovoltaic Cells on P-Type LDE Wafers

The paste compositions of Example 6a and 7a were used to prepare bus bar/finger front-side electrodes on p-type LDE wafers for the photovoltaic cells of Examples 6b and 7b. Full coverage back side electrodes were prepared with PV35A paste composition. Electrical test results for these cells after firing are shown in Table V.

TABLE V
Electrical Properties of P-Type LDE Monocrystalline Si Solar Cells

| | Eff. | FF | Ra |
|---|---|---|---|
| Example | (%) | (%) | (Ω) |
| 6b | 17.72 | 75.9 | 0.153 |
| 7b | 17.40 | 75.8 | 0.155 |

The results of Examples 1-7 further establish that the present alkali metal vanadium oxide-based paste compositions can be used to fabricate front-side electrodes for both n-type and p-type PV cells and that electrodes can even be formed on the more difficult to contact lightly doped, p-type LDE emitters. The results also establish that similar results can obtained whether the cesium metavanadate is commercially sourced or lab-synthesized.

### Examples 8a-12a

### Preparation of Conductive Paste Compositions Containing Cesium Metavanadate and Titanium-Based Additives

The experiments of the previous examples were extended by formulating conductive pastes that include certain titanium-containing additives along with cesium metavanadate.

Representative Examples 8a-12a are listed in Table VI. The experimental procedures described above were used to prepare the base paste compositions. In each case, the paste composition comprised about 86% Ag powder, 1.8% CsVO₃, and 12% organic vehicle, by weight. The various additives were sieved to −325 mesh and then incorporated by a subsequent Thinky®-mixing step at the levels indicated.

TABLE VI
Cesium Metavandate Paste with Transition Metal-Based Additives

| Example | additive | wt. % additive |
|---|---|---|
| 8a | TiC | 1.5 |
| 9a | TiC | 1.4 |
| 10a | Nano-TiC | 0.75 |
| 11a | TiO₂ | 1.5 |
| 12a | TiN | 1.5 |

### Examples 8b-12b

### Fabrication and Testing of N-Type Photovoltaic Cells Using Conductive Pastes Containing Cesium Metavanadate and Ti-Based Additives

The paste compositions of Examples 8a-12a were used to prepare front-side and back-side electrodes, respectively, on n-type wafers for the photovoltaic cells of Examples 8b-12b. Electrodes on both sides were formed in the aforementioned bus-bar/finger configuration. The procedures described above were used to fabricate and characterize the cells. Results of the electrical testing are shown in Table VII.

TABLE VII
Electrical Properties of N-Type Photovoltaic Cells

| | | Eff. | FF | Ra |
|---|---|---|---|---|
| Example | additive | (%) | (%) | (Ω) |
| 8b | TiC | 17.1 | 71.2 | 0.190 |
| 9b | TiC | 16.9 | 70.6 | 0.200 |
| 10b | nano-TiC | 17.1 | 72.8 | 0.166 |
| 11b | TiO₂ | 17.3 | 72.3 | 0.166 |
| 12b | TiN | 17.3 | 72.8 | 0.165 |

The results in Table VII demonstrate that the electrical performance of cells having electrodes made with the CsVO₃-based pastes of Examples 1a to 4a can be matched or enhanced by inclusion of certain Ti-based additives, as indicated by equal or higher conversion efficiencies and/or lower apparent series resistance Rₐ exhibited by the cells of Examples 1b to 4b.

### Examples 13a-15a

### Preparation of Conductive Paste Compositions Containing Cesium Metavanadate and Phosphide or Carbide Additives

Examples 8a-12a were extended by formulating paste compositions containing a cesium metavanadate oxide component and phosphide or carbide additives, as listed in Table VIII. In each case, the paste composition comprised about 86% Ag powder and 12% organic vehicle, by weight, and CsVO₃, as indicated. The various additives were sieved to −325 mesh and then incorporated by a subsequent Thinky®-mixing step at the levels indicated.

TABLE VIII
Cesium Metavandate Pastes with Phosphide And Carbide Additives

| | wt. % CsVO₃ | | |
|---|---|---|---|
| Example | before addition | additive | wt. % additive |
| 13a | 1.5 | Ni₂P | 0.7 |
| 14a | 1.5 | TaP | 0.7 |
| 15a | 1.8 | VC | 1.5 |

### Examples 13b-15b

### Fabrication and Testing of N-Type Photovoltaic Cells Using Conductive Pastes Containing Cesium Metavanadate and Additives

The paste compositions of Examples 13a-15a and PV17F were used to prepare front-side and back-side electrodes, respectively, on n-type wafers for the photovoltaic cells of Examples 13b-15b. Electrodes on both sides were formed in bus-bar/finger configuration. The procedures described above were used to fabricate and characterize the cells. Results of the electrical testing are shown in Table IX.

TABLE IX
Electrical Properties of N-Type Photovoltaic Cells

| | | wt. % | Eff. | FF | Ra |
|---|---|---|---|---|---|
| Example | additive | additive | (%) | (%) | (Ω) |
| 13b | Ni₂P | 0.7 | 16.2 | 69.6 | 0.236 |
| 14b | TaP | 0.7 | 16.5 | 71.8 | 0.204 |
| 15b | VC | 1.5 | 4.5 | 27.9 | 2.80 |

The photovoltaic cells of Examples 13b and 14b with phosphide additives are thus seen to exhibit attractive electrical properties. The inclusion of VC resulted in cells (Example 15b) that, while still operative to convert incident light into electrical energy, did not exhibit properties matching those made with the pastes containing phosphide additives.

### Examples 16b to 17b

### Fabrication and Testing of P-Type Photovoltaic Cells with Lightly Doped Emitters

The formation of electrodes contacting front-side, n-type emitter regions of p-type wafers was tested. Front-side bus bar/finger electrodes were fabricated on monocrystalline LDE wafers with the pastes of Examples 8a-9a above, and using the same methods employed for Examples 6a-7a. Full-coverage back-side electrodes were formed using PV35A paste composition.

The electrical characteristics of the resulting cells of Examples 16b-17b were then measured using the same procedure as before, yielding the results shown in Table X.

TABLE X
Electrical Properties of P-Type Photovoltaic
Cells Prepared on Mono-crystalline LDE Wafers

| | | Eff. | FF | Ra |
|---|---|---|---|---|
| Example | Front Ag Paste | (%) | (%) | (Ω) |
| 16b | 8a | 17.46 | 76.62 | 0.155 |
| 17b | 9a | 17.21 | 75.76 | 0.169 |

It is generally understood to be more difficult to establish good electrical contact between Ag electrodes and lightly-doped n-type emitters in a p-base cell than with more heavily doped emitters. Poor electrical contact in turn decreases cell conversion efficiency by increasing losses attributable to the cell's own source impedance. Thus, it is surprising and unexpected that the present AVO₃-based paste compositions permit formation of front-side electrodes on p-base wafers with lightly doped n-type emitters, producing photovoltaic cells that exhibit efficiencies higher than those attained in cells made with existing paste compositions.

### Examples 18a-22a

### Preparation of Conductive Paste Compositions Containing Cesium Metavanadate and Additives

Additional examples of paste compositions containing 1.8 wt. % CsVO₃ and various oxide and non-oxide additives were formulated, as listed in Table XI. A paste composition masterbatch was prepared as described above, with a portion reserved as Example 18a. Examples 19a-21a were prepared to ascertain the effect of various additives, which were added to the masterbatch paste composition by a Thinky® mixing operation, as further described above. The paste composition of Example 22a was prepared by directly roll milling the Li₂RuO₃ additive into the masterbatch paste composition.

TABLE XI
Cesium Metavandate Paste Compositions with Additives

| Example | additive | wt. % additive |
|---|---|---|
| 18a | — | — |
| 19a | Zn metal | 1.5 |
| 20a | ZnO | 1.5 |
| 21a | HfC | 1.5 |
| 22a | Li₂RuO₃ | 0.1 |

### Examples 18b-22b

### Fabrication and Testing of P-Type Photovoltaic Cells with Lightly Doped Emitters Using Conductive Pastes Containing Cesium Metavanadate and Additives

The paste compositions of Examples 18a to 22a were used to prepare front-side electrodes in the bus bar/finger configuration for the photovoltaic cells of Examples 18b-22b listed in Table XII below; PV35C paste was used to prepare full coverage back-side electrodes on p-type monocrystalline wafers. The procedures described above for Examples 16b-17b were used to fabricate and characterize the cells. Results of the electrical testing are shown in Table XII.

TABLE XII
Electrical Properties of P-Type Mono-crystalline Photovoltaic
Cells with Lightly Phosphorus-Doped Emitters

| | | Eff. | FF | Ra |
|---|---|---|---|---|
| Example | Additive | (%) | (%) | (Ω) |
| 18b | — | 17.57 | 76.15 | 0.152 |
| 18b (repeat) | — | 16.97 | 74.6 | 0.161 |
| 19b | Zn metal | 16.36 | 72.2 | 0.196 |
| 20b | ZnO | 16.89 | 74.4 | 0.185 |
| 21b | HfC | 16.92 | 74.6 | 0.169 |
| 22b | Li₂RuO₃ | 17.31 | 76.15 | 0.165 |

### Examples 23a-24a

### Preparation of Conductive Paste Compositions Containing Cesium Metavanadate and Nitride Additives

The experiments of Examples 18-22 were extended by formulating conductive pastes that include certain nitride-containing additives along with cesium metavanadate.

The paste compositions of Examples 23a-24a are listed in Table XIII. They were formulated by mixing pre-combined 1.8 wt. % CsVO₃, about 85 wt. % Ag powder, and 1.5 wt. % of the desired additive with about 8-10 wt. % organic vehicle (percentages by weight of the paste composition), as described above, with allowance for a small solvent hold-back.

TABLE XIII
Cesium Metavandate Paste with Nitride Additives

| Example | additive |
|---|---|
| 23a | BN, hex. |
| 24a | ZrN |

### Examples 23b-24b

### Fabrication and Testing of Lightly Doped P-Type Photovoltaic Cells Using Conductive Pastes Containing Cesium Metavanadate and Nitride Additives

For Examples 23b-24b, the paste compositions of Examples 23a-24a were used to prepare front-side electrodes in the bus bar/finger configuration on p-type, LDE wafers. PV35A paste was used to prepare full coverage back side electrodes. The procedures described above for Examples 18b-22b were used to fabricate and characterize the cells. Results of the electrical testing are shown in Table XIV.

TABLE XIV
Electrical Properties of P-Type Mono-crystalline Photovoltaic
Cells with Lightly Phosphorus-Doped Emitters

| | | Eff. | FF | Ra |
|---|---|---|---|---|
| Example | Additive | (%) | (%) | (Ω) |
| 23b | BN, hex. | 15.88 | 70.3 | 0.265 |
| 24b | ZrN | 17.02 | 76.9 | 0.156 |

### Examples 25a-26a

### Preparation of Conductive Paste Compositions Containing Cesium Vanadium Oxide

The results of Examples 1 to 4 were extended by formulating pastes wherein the cation ratio of Cs:V of the cesium vanadium oxide component was varied from the 1:1 ratio of stoichiometric CsVO₃ and certain non-oxide additives were included.

Powders of cesium vanadium oxide compositions with different Cs:V ratios were prepared by reacting suitable reagent powders (e.g., Cs₂CO₃ and V₂O₅) at sufficiently high temperature to achieve sintering or melting, then comminuting the solidified mass to form a suitable oxide for incorporation in the present paste composition. Powder X-ray diffraction revealed that the resultant powder was non-glassy, and comprised ˜32 wt. % CsVO₃ (Cesium Metavanadate) and ˜68 wt. % CsV₂O_{5.5} (Cesium Vanadium Oxide).

This powder, hereafter referred to as “Cs0.38V0.62Ox”, was used as the oxide component in the conductive Ag paste compositions listed in Table XV. The procedure used to prepare the pastes was the same as the one described for Examples 8a-12a. First, the desired amounts of Ag powder, cesium vanadium oxide composition, and organic vehicle were Thinky-mixed together and roll milled, as described for Examples 1a-4a. Mg₂Si powder was sieved through a 325 mesh screen and then combined with the paste masterbatch by a Thinky mixing procedure.

TABLE XV
Paste Compositions Containing a Mixture
of Crystalline Cesium-Vanadium Oxides

| | | wt % cesium vanadium | | wt. % |
|---|---|---|---|---|
| Example | Cs/(Cs + V) | oxide before additive | additive | additive |
| 25a | 0.38 | 2.0 | Mg₂Si | 1.0 |
| 26a | 0.38 | 1.0 | Mg₂Si | 1.0 |

### Examples 25b-26b

### Fabrication and Testing of Photovoltaic Cells

The paste compositions of Examples 25a-26a were used to prepare bus bar/finger front-side electrodes for n-type photovoltaic cells using the same 28 mm×28 mm cut-down square wafers used for the cells of Examples 5b and 6b above. PV17F paste was used to form back-side electrodes with the same bus bar/finger configuration. The cells were fired and electrically tested as described above, yielding the properties that are set forth in Table XVI.

TABLE XVI
Electrical Properties of N-Type Photovoltaic Cells

| | | Eff. | FF | Ra |
|---|---|---|---|---|
| Example | additive | (%) | (%) | (Ω) |
| 25b | Mg₂Si | 16.0 | 69.1 | 0.221 |
| 26b | Mg₂Si | 16.2 | 69 | 0.230 |

### Examples 27a-36a

### Preparation of Cesium Vanadium Oxide Conductive Paste Compositions

Cesium vanadium oxide-based compositions with additional intimately mixed oxides were prepared in the manner described above. Requisite amounts of CsCO₃, V₂O₅, Al₂O₃, SiO₂, TiO₂, and B₂O₃, as listed in Table XVII below, were combined, melted together in a Pt crucible, cooled, and then pulverized and milled to produce a suitable powder. Paste compositions suitable for screen printing were made by Thinky® mixing the various oxide components with about 86-87% Ag powder and about 9% organic vehicle (by weight) as before. The amount of the oxide component included in each paste is shown in Table XVII.

TABLE XVII
Cesium Vanadium Oxide-based Paste Compositions

| | oxide | cation % | cation % | cation % | cation % | cation % | | cation % | Cs/ |
|---|---|---|---|---|---|---|---|---|---|
| Example | (wt. %) | Cs | V | Al | Si | Ti | cation % | B | (Cs + V) |
| 27a | 2.0 | 42.5 | 42.5 | | | 15 | | | 0.500 |
| 28a | 2.0 | 45 | 45 | | | 10 | | | 0.500 |
| 29a | 2.0 | 46.25 | 46.25 | | | 7.5 | | | 0.500 |
| 30a | 2.0 | 48.5 | 48.5 | 2 | 1 | | | | 0.500 |
| 31a | 2.0 | 47.5 | 47.5 | | | 5 | | | 0.500 |
| 32a | 1.8 | 46.25 | 46.25 | | | | | 7.5 | 0.500 |
| 33a | 1.8 | 42.5 | 42.5 | | | | | 15 | 0.500 |
| 34a | 2.55 | 31.15 | 31.15 | | | 37.70 | | | 0.500 |
| 35a | 3.30 | 22.60 | 22.60 | | | 54.80 | | | 0.500 |
| 36a | 2.12 | 39.70 | 39.70 | | | 20.60 | | | 0.500 |

### Examples 27b-36b

### Preparation and Testing of Photovoltaic Cells on P-Type, LDE Wafers

Photovoltaic cells for Examples 27b-36b were fabricated on 28 mm×28 mm cut-down, p-type LDE wafers using the paste compositions of Examples 27a-36a, respectively, to fabricate front-side electrodes in the aforementioned bus bar/finger configuration. PV35A paste was used to fabricate full-coverage back-side electrodes. The photovoltaic cells of Examples 27b-36b were electrically tested as before, yielding results shown in Table XVIII.

TABLE XVIII
Electrical Properties of Photovoltaic Cells

| | Eff. | FF | Ra |
|---|---|---|---|
| Example | (%) | (%) | (Ω) |
| 27b | 17.00 | 75.00 | 0.1640 |
| 28b | 17.15 | 75.70 | 0.1627 |
| 29b | 17.00 | 74.70 | 0.1666 |
| 30b | 17.30 | 75.40 | 0.1570 |
| 31b | 17.50 | 76.10 | 0.1530 |
| 32b | 17.45 | 75.92 | 0.1620 |
| 33b | 17.03 | 74.74 | 0.1750 |
| 34b | 17.49 | 76.14 | 0.1625 |
| 35b | 17.21 | 75.16 | 0.1759 |
| 36b | 17.13 | 74.56 | 0.1853 |

### Examples 37a-39a

### Preparation of Conductive Paste Compositions Containing Alkali Metal Metal Metavanadates

Paste compositions comprising stoichiometric metavanadates of the alkali metals Na, K, and Rb as the oxide component were prepared as Examples 37a-39a, as set forth in Table XIX below. The various metavanadates were prepared by melting together the alkali metal carbonate and V₂O₅, then quenching and pulverizing the melt. The resulting fine powder (about 2 wt. %) was combined with Ag powder (about 86 wt. %) and organic vehicle (about 12 wt. %) from the masterbatch, as described above.

TABLE XIX
Alkali Metal Metavanadate Compositions

| | cation % | cation % | cation % | cation % |
|---|---|---|---|---|
| Sample # | Rb | K | Na | V |
| 37a | | | 50 | 50 |
| 38a | | 50 | | 50 |
| 39a | 50 | | | 50 |

### Examples 37b to 39b

### Preparation and Testing of Photovoltaic Cells on P-type, LDE Wafers

The paste compositions of Examples 37a-39a were used to prepare bus bar/finger front-side electrodes for p-type photovoltaic cells fabricated on cut down LDE wafers as Examples 37b-39b, respectively. PV35A paste was used to form full-coverage back side electrodes. The cells were fired and electrically tested as described above, yielding the properties that are set forth in Table XX.

TABLE XX
Electrical Properties of Photovoltaic Cells
Containing Alkali Metal Metavanadates (AVO₃)

| | Cation | Eff. | FF | Ra | Voc |
|---|---|---|---|---|---|
| Example | A | (%) | (%) | (Ω) | (mV) |
| 37b | Na | 6.00 | 30.20 | 1.953 | 608 |
| 38b | K | 17.00 | 75.60 | 0.168 | 623 |
| 39b | Rb | 17.20 | 75.90 | 0.154 | 627 |

It is evident that the photovoltaic cells of Examples 38b-39b, exhibit electrical properties comparable to those of the cells of Examples 1 to 4, demonstrating that the potassium and rubidium metavanadates function in a manner similar to that of cesium metavanadate, while the sodium metavanadate-based cells of Example 37b exhibited less attractive, but still functional, properties.

### Examples 40a-45a

### Preparation of Conductive Paste Compositions Containing Mixed Alkali Metal Metavanadates

Paste compositions comprising stoichiometric metavanadates of a combination of the alkali metals Na, K, and Rb as the oxide component were prepared as Examples 40a-45a, as set forth in Table XXI below. The various metavanadates were prepared by melting together the required alkali metal carbonates and V₂O₅, then quenching and pulverizing the melt. The resulting fine powder (1.8 wt. %) was combined with Ag powder (˜86-87 wt. %) and organic vehicle (˜10 wt. %) from the organic masterbatch, as described above.

TABLE XXI
Mixed Alkali Metal Metavanadate Compositions

| | cation % | cation % | cation % | cation % | cation % |
|---|---|---|---|---|---|
| Sample # | Cs | Rb | K | Na | V |
| 40a | 25 | 25 | | | 50 |
| 41a | 25 | | 25 | | 50 |
| 42a | | 25 | 25 | | 50 |
| 43a | 16.67 | 16.67 | 16.67 | | 50 |
| 44a | 37.5 | | 12.5 | | 50 |
| 45a | 12..5 | | 37.5 | | 50 |

### Examples 40b-45b

### Preparation and Testing of Photovoltaic Cells on P-type, LDE Wafers

The paste compositions of Examples 40a-45a were used to prepare bus bar/finger front-side electrodes for p-type photovoltaic cells fabricated on cut-down LDE wafers as Examples 40b-45b, respectively. PV35A paste was used to form full-coverage back side electrodes. The cells were fired and electrically tested as described above, yielding the properties that are set forth in Table XXII.

TABLE XXII
Electrical Properties of Photovoltaic Cells
Containing Alkali Metal Metavanadates (AVO₃)

| | | Eff. | FF | Ra |
|---|---|---|---|---|
| Example | Cation | (%) | (%) | (Ω) |
| 40b | Cs, Rb | 17.39 | 75.74 | 0.156 |
| 41b | Cs, K | 17.14 | 74.38 | 0.180 |
| 42b | Rb, K | 14.61 | 64.02 | 0.399 |
| 43b | Cs, Rb, K | 17.39 | 75.70 | 0.163 |
| 44b | Cs, K | 17.01 | 74.78 | 0.173 |
| 45b | Cs, K | 13.70 | 60.38 | 0.461 |

The photovoltaic cells of Examples 40b-45b exhibit electrical properties similar to those of Examples 1a-4a, confirming that some or all of the Cs in the present paste composition can be replaced by other alkali metals, especially Rb and K.

### Examples 46a-50a

### Preparation of Conductive Paste Compositions

The experiments of Examples 1-4, wherein the first oxide-based component was provided by cesium metavanadate, were extended by formulating alkali metal vanadium oxide compositions with alkali metals besides solely Cs and/or by varying the alkali metal to vanadium cation ratio from the strict 1:1 ratio in the stoichiometric alkali metal metavanadates. Some of the exemplary paste compositions further included other cations intimately mixed into the alkali metal vanadium oxide compositions. In each case, the alkali metal vanadium oxide composition was prepared by combining the requisite amounts of the alkali metal carbonate(s), V₂O₅, and oxides of the additional cations, if any, and then melting, solidifying, pulverizing, and milling the solidified mass as described above. The oxide component (1.8 wt. %), Ag powder (86.2 wt. %), and organic vehicle (˜9 wt. %) were combined in the manner set forth above to form the representative compositions shown in Table XXIII below.

TABLE XXIII
Pastes with Alkali Metavandates and Mixtures Thereof

| | cation % | cation % | cation % | cation % | cation % | cation % | cation % | alkali/ |
|---|---|---|---|---|---|---|---|---|
| Example | Cs | Rb | K | Li | V | Al | Si | (alkali + V) |
| 46a | | 53 | | | 45 | 2 | | 0.541 |
| 47a | | 27.8 | 21 | | 48.7 | 1.7 | 0.8 | 0.501 |
| 48a | 27.5 | | | 13.8 | 58.7 | | | 0.413 |
| 49a | 45 | | | | 55 | | | 0.450 |
| 50a | 55 | | | | 43 | 2 | | 0.561 |

### Examples 46b-50b

### Fabrication and Testing of Photovoltaic Cells

Photovoltaic cells for Examples 46b-50b were formed on cut-down, n-type wafers using the paste compositions of Examples 46a-50a, respectively, to prepare bus bar/finger front-side electrodes; PV17F paste was used to form bus bar/finger back-side electrodes. Results of electrical testing of these cells after firing are shown in Table XXIV.

TABLE XXIV
Electrical Properties of N-Type Photovoltaic Cells

| | Eff. | FF | Ra |
|---|---|---|---|
| Example | (%) | (%) | (Ω) |
| 46b | 17.01 | 72.2 | 0.18 |
| 47b | 16.01 | 72.8 | 0.22 |
| 48b | 13.31 | 57.5 | 0.43 |
| 49b | 16.47 | 72.6 | 0.21 |
| 50b | 15.73 | 66.7 | 0.27 |

These electrical properties demonstrate that paste compositions containing an oxide component comprising mixed alkali metal and vanadium cations and optionally, additional oxides, can be used successfully to create photovoltaic cell electrodes.

Having thus described the invention in rather full detail, it will be understood that this detail need not be strictly adhered to but that further changes and modifications may suggest themselves to one skilled in the art, all falling within the scope of the invention as defined by the subjoined claims.

For example, a skilled person would recognize that the choice of raw materials could unintentionally include impurities that may be incorporated into the alkali metal vanadium oxide composition or other paste constituents during processing. These incidental impurities may be present in the range of hundreds to thousands of parts per million. Impurities commonly occurring in industrial materials used herein are known to one of ordinary skill.

The presence of the impurities would not substantially alter the chemical and rheological properties of the oxide-based component, the alkali metal vanadium oxide composition therein, paste compositions made with the oxide-based component and/or alkali metal vanadium oxide composition, or the electrical properties of a fired device manufactured using the paste composition. For example, a solar cell employing a conductive structure made using the present paste composition may have the efficiency and other electrical properties described herein, even if the paste composition includes impurities.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

In this specification, unless explicitly stated otherwise or indicated to the contrary by the context of usage, amounts, sizes, ranges, formulations, parameters, and other quantities and characteristics recited herein, particularly when modified by the term “about,” may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value.

What is claimed is:

1. A paste composition, comprising:
an inorganic solids portion that comprises:
(a) a first, oxide-based component comprising an alkali metal vanadium oxide composition,
(b) an optional second, non-metallic, non-oxide component,
(c) a source of electrically conductive metal; and
an organic vehicle in which the constituents of the inorganic solids portion are dispersed.

2. The paste composition of claim 1, wherein the alkali metal comprises at least 50% of K, Rb, Cs, or a mixture thereof by cation percentage.

3. The paste composition of claim 1, wherein the oxide-based component comprises:
(a) alkali metal cations in a cation percentage “a” ranging from 15 to 50;
(b) vanadium cations in a cation percentage “b” ranging from 20 to 70;
(c) alkaline earth metal cations in a cation percentage “c” ranging from 0 to 20; and
(d) phosphorus cations in a cation percentage “d” ranging from 0 to 20, and
wherein the cation percentages a, b, c, and d are based on the total oxide-based component.

4. The paste composition of claim 1, wherein the alkali metal vanadium oxide composition comprises alkali metal cations and V cations in respective cation percentages of “x” and “y”, and wherein a value of the sum “w”=(x+y) is between a lower limit of 50 cation % and an upper limit of 100 cation %.

5. The paste composition of claim 1, wherein the alkali metal vanadium oxide composition comprises alkali metal cations and V cations in respective cation percentages of “x” and “y”, and wherein a value of the ratio “z”=x/(x+y) is between a lower ratio limit of 0.3 and an upper ratio limit of 0.65.

6. The paste composition of claim 1, wherein the alkali vanadium oxide composition comprises at least one of an alkali metal metavanadate having the formula AVO₃, a crystalline alkali metal vanadium oxide having a formula (A²)V₂O_{5.5}, or a crystalline alkali metal vanadium oxide having a formula (A³)V₃O₈, wherein A, A², and A³ are each separately at least one of Li, Na, K, Rb, or Cs.

7. The paste composition of claim 1, wherein the alkali metal vanadium oxide comprises in intimate admixture additional cations of at least one of B, Al, Mg, Ca, Sr, Ba, Ti, Mn, Fe, Co, Ni, Cu, Zn, Zr, Nb, Te, Si, Mo, Hf, Ta, W, Pb, Ag, Ga, Ge, In, Sn, Sb, Se, Ru, Bi, P, Y, or La or the other lanthanide elements.

8. The paste composition of claim 7, wherein the additional cations are present in an aggregate amount up to an upper admixture limit of 35% of the total cations in the alkali metal vanadium oxide composition.

9. The paste composition of claim 1, wherein the oxide component separately comprises at least one additional discrete oxide selected from the group consisting of oxides of one or more of Al, Li, Na, K, Rb, Cs, Mg, Ca, Sr, Ba, Ti, V, Mn, Fe, Co, Ni, Cu, Zn, Zr, Nb, Te, Si, Mo, Hf, Ta, W, Pb, Ag, Ga, Ge, In, Sn, Sb, Se, Ru, Bi, P, Y, La and the other lanthanide elements, and mixtures thereof, and a substance which forms such an oxide upon firing.

10. The paste composition of claim 1, wherein the first component is present in an amount between a first lower limit of 0.25% and a first upper limit of 10% and the second component is present in an amount ranging from a second lower limit of 0% and a second upper limit of 5%, the amounts being measured by weight percentage of the paste composition.

11. The paste composition of claim 1, wherein the second component is at least one of a phosphide, a carbide, a silicide, or a nitride.

12. The paste composition of claim 11, wherein the second component comprises at least one of Ni₂P, TaP, TiC, HfC, Mg₂Si, TiN, ZrN, or BN.

13. The paste composition of claim 1, wherein the first component is at least partially amorphous.

14. The paste composition of claim 1, wherein the source of the electrically conductive metal is an Ag metal powder.

15. The paste composition of claim 1, wherein the electrically conductive metal is substantially Al-free.

16. A process for forming an electrically conductive structure on a substrate, the process comprising:
(a) providing a substrate having opposed first and second major surfaces;
(b) applying a paste composition of claim 1 onto a first preselected portion of the first major surface; and
(c) firing the substrate and paste composition thereon, whereby the electrically conductive structure is formed on the substrate.

17. The process of claim 16, further comprising applying the paste composition onto a separate second preselected portion of one of the major surfaces, and wherein the firing further results in the formation of separate electrically conductive structures on the respective preselected portions of the substrate.

18. The process of claim 17, wherein the first portion consists essentially of n-type material and the second portion consists essentially of p-type material.

19. The process of claim 18, wherein the first and second preselected portions are respectively situated on the first and second major surfaces.

20. An article comprising a substrate and an electrically conductive structure thereon, the article having been formed by the process of claim 16.

21. An electrode contacting a p-type region of a silicon semiconductor, the electrode comprising an electrically conductive structure that has been formed by the process of claim 16.

22. An electrode contacting an n-type region of a silicon semiconductor, the electrode comprising an electrically conductive structure that has been formed by the process of claim 16.
